(19) United States
(12) Patent Application Publication
(10) Pub. No.: US 2025/0380447 A1
(43) Pub. Date: Dec. 11, 2025

(54) SEMICONDUCTOR APPARATUS AND METHOD OF MANUFACTURING SEMICONDUCTOR APPARATUS

(71) Applicant: Mitsubishi Electric Corporation, Tokyo (JP)

(72) Inventor: Junya MIWA, Tokyo (JP)

(73) Assignee: Mitsubishi Electric Corporation, Tokyo (JP)

(21) Appl. No.: 19/070,276

(22) Filed: Mar. 4, 2025

(30) Foreign Application Priority Data
Jun. 10, 2024 (JP) 2024-093876

(51) Int. Cl. H10D 30/66; H10D 30/01; H10D 62/10; H10D 62/13; H10D 64/23

(52) U.S. Cl. CPC H10D 30/66; H10D 30/0291; H10D 62/102; H10D 62/115; H10D 62/124; H10D 62/153; H10D 64/252

(57) ABSTRACT

According to the present disclosure, a semiconductor apparatus comprises a semiconductor substrate including a drift layer of a first conduction type, a first base layer of the first conduction type and a second base layer of a second conduction type, a source layer of the first conduction type having higher impurity concentration than the first base layer, and a contact layer of the second conduction type having higher impurity concentration than the second base layer, a gate oxide film, a gate electrode, an interlayer insulating film provided on the semiconductor substrate and including a plurality of first contact holes that expose parts of the source layer and a plurality of second contact holes that expose parts of the contact layer, a source electrode, and a drain electrode. The first contact holes and the second contact holes are separated by the interlayer insulating film.

### BACKGROUND OF THE INVENTION

### Field

The present disclosure relates to a semiconductor apparatus and a method of manufacturing a semiconductor apparatus.

### Background

JP H10-233503 A discloses a planar type SiC-MOSFET. A planar type MOSFET is suitable for a high-speed drive use because the planar type MOSFET has a smaller parasitic capacitance compared with a trench type MOSFET.

However, in the planar type MOSFET, since a cell repeating direction and a channel length direction are the same, a channel length needs to be reduced when cell pitch shrink is performed. As a result, there is a problem in that short circuit tolerance decreases.

### SUMMARY

In view of the above-described problems, an object of the present disclosure is to provide a semiconductor apparatus and a method of manufacturing a semiconductor apparatus that can improve short circuit tolerance.

The features and advantages of the present disclosure may be summarized as follows.

A semiconductor apparatus according to the present disclosure includes: a semiconductor substrate including a drift layer of a first conduction type, a first base layer of the first conduction type and a second base layer of a second conduction type provided side by side with each other on an upper surface side of the drift layer, a source layer of the first conduction type selectively provided on an upper surface side of the second base layer and having higher impurity concentration than the first base layer, and a contact layer of the second conduction type selectively provided on the upper surface side of the second base layer and having higher impurity concentration than the second base layer; a gate oxide film provided on the first base layer, the second base layer, the source layer, and the contact layer; a gate electrode provided on the gate oxide film; an interlayer insulating film provided on the semiconductor substrate to cover the gate oxide film and the gate electrode and including a plurality of first contact holes that expose parts of the source layer and a plurality of second contact holes that expose parts of the contact layer; a source electrode connected to the source layer via the first contact holes and connected to the contact layer via the second contact holes; and a drain electrode connected to a lower surface side of the drift layer, wherein the first contact holes and the second contact holes are separated by the interlayer insulating film.

Other and further objects, features and advantages of the disclosure will appear more fully from the following description.

### BRIEF DESCRIPTION OF DRAWINGS

FIG. 1 is a plan view illustrating a configuration of a semiconductor apparatus according to a first embodiment of the present disclosure.

FIG. 2 is a sectional view taken along A-A′ in FIG. 1.

FIG. 3 is a sectional view taken along B-B′ in FIG. 1.

FIG. 4 is a sectional view taken along C-C′ in FIG. 1.

FIG. 5 is a first diagram illustrating a process for manufacturing a semiconductor apparatus according to the first embodiment of the present disclosure.

FIG. 6 is a second diagram illustrating the process for manufacturing the semiconductor apparatus according to the first embodiment of the present disclosure.

FIG. 7 is a third diagram illustrating the process for manufacturing the semiconductor apparatus according to the first embodiment of the present disclosure.

FIG. 8 is a fourth diagram illustrating the process for manufacturing the semiconductor apparatus according to the first embodiment of the present disclosure.

FIG. 9 is a fifth diagram illustrating the process for manufacturing the semiconductor apparatus according to the first embodiment of the present disclosure.

FIG. 10 is a sixth diagram illustrating the process for manufacturing the semiconductor apparatus according to the first embodiment of the present disclosure.

FIG. 11 is a seventh diagram illustrating the process for manufacturing the semiconductor apparatus according to the first embodiment of the present disclosure.

FIG. 12 is an eighth diagram illustrating the process for manufacturing the semiconductor apparatus according to the first embodiment of the present disclosure.

FIG. 13 is a ninth diagram illustrating the process for manufacturing the semiconductor apparatus according to the first embodiment of the present disclosure.

FIG. 14 is a tenth diagram illustrating the process for manufacturing the semiconductor apparatus according to the first embodiment of the present disclosure.

FIG. 15 is a plan view illustrating a configuration of a semiconductor apparatus according to a second embodiment of the present disclosure.

FIG. 16 is a sectional view taken along A-A′ in FIG. 15.

FIG. 17 is a sectional view taken along B-B′ in FIG. 15.

FIG. 18 is a sectional view taken along C-C′ in FIG. 15.

FIG. 19 is a plan view illustrating a configuration of a semiconductor apparatus according to a third embodiment of the present disclosure.

FIG. 20 is a sectional view taken along A-A′ in FIG. 19.

FIG. 21 is a sectional view taken along B-B′ in FIG. 19.

FIG. 22 is a sectional view taken along C-C′ in FIG. 19.

FIG. 23 is a plan view illustrating a configuration of a semiconductor apparatus according to a fourth embodiment of the present disclosure.

FIG. 24 is a sectional view taken along A-A′ in FIG. 23.

FIG. 25 is a sectional view taken along B-B′ in FIG. 23.

FIG. 26 is a sectional view taken along C-C′ in FIG. 23.

FIG. 27 is a plan view illustrating a configuration of a semiconductor apparatus according to a fifth embodiment of the present disclosure.

FIG. 28 is a sectional view taken along A-A′ in FIG. 27.

FIG. 29 is a sectional view taken along B-B′ in FIG. 27.

FIG. 30 is a sectional view taken along C-C′ in FIG. 27.

FIG. 31 is a plan view illustrating a configuration of a semiconductor apparatus according to a sixth embodiment of the present disclosure.

FIG. 32 is a sectional view taken along A-A′ in FIG. 31.

FIG. 33 is a sectional view taken along B-B′ in FIG. 31.

FIG. 34 is a sectional view taken along C-C′ in FIG. 31.

FIG. 35 is a plan view illustrating a configuration of a semiconductor apparatus according to a seventh embodiment of the present disclosure.

FIG. 36 is a sectional view taken along A-A′ in FIG. 35.

FIG. 37 is a sectional view taken along B-B′ in FIG. 35.

FIG. 38 is a sectional view taken along C-C′ in FIG. 35.

FIG. 39 is a plan view illustrating a configuration of a semiconductor apparatus according to an eighth embodiment of the present disclosure.

FIG. 40 is a sectional view taken along A-A′ in FIG. 39.

FIG. 41 is a sectional view taken along B-B′ in FIG. 39.

FIG. 42 is a sectional view taken along C-C′ in FIG. 39.

FIG. 43 is a plan view illustrating a configuration of a semiconductor apparatus according to a first modification of the second embodiment of the present disclosure.

FIG. 44 is a plan view illustrating a configuration of a semiconductor apparatus according to a second modification of the second embodiment of the present disclosure.

### DESCRIPTION OF EMBODIMENTS

Semiconductor apparatuses and methods of manufacturing semiconductor apparatuses according to embodiments are described with reference to the drawings. The same or corresponding components are denoted by the same reference numerals and signs and repeated description of the components is sometimes omitted.

### First Embodiment

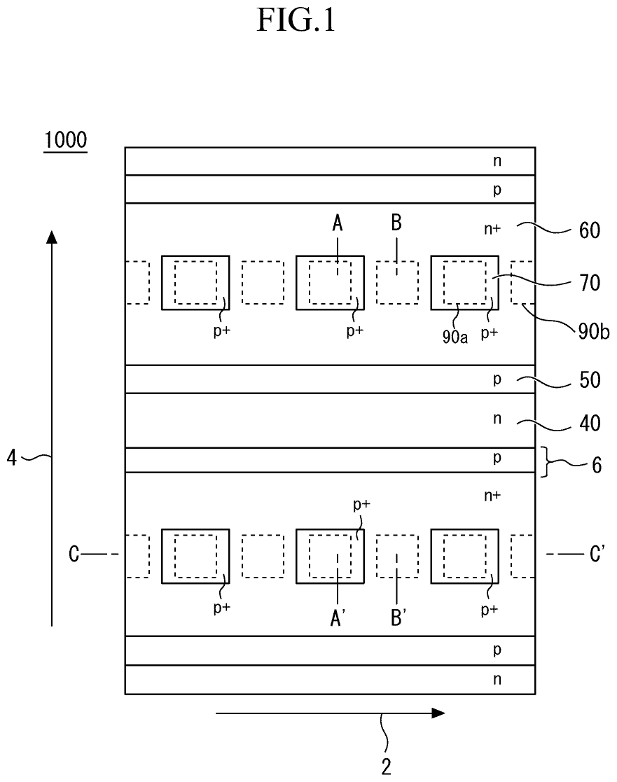

FIG. 1 is a plan view illustrating a configuration of a semiconductor apparatus according to a first embodiment of the present disclosure. FIG. 1 illustrates a plane layout of a cell region of a semiconductor apparatus 1000 that is a planar type MOSFET.

Note that, in FIG. 1, for convenience of description, a source electrode, an interlayer insulating film, a gate electrode, and a passivation film are not illustrated. The same applies in plan views illustrating configurations of semiconductor apparatuses.

The semiconductor apparatus 1000 includes an n type base layer 40 extending in a first direction 2. P type base layers 50, extending in the first direction 2, are positioned on both sides in a second direction 4. The width in the second direction 4 of the p type base layers 50 is referred to as channel length 6. N+ type source layers 60, extending in the first direction 2, are positioned on sides of the p type base layers 50 where the n type base layer 40 is not positioned in the second direction 4. The n+ type source layers 60 have higher impurity concentration than the n type base layer 40.

Parts of the n+ type source layers 60 are covered with p+ type contact layers 70. The p+ type contact layers 70 have higher impurity concentration than the p type base layers 50. The p+ type contact layers 70 are positioned at fixed intervals in the first direction 2 to discretely cover the n+ type source layers 60.

Here, the n type base layer 40, the p type base layers 50, the n+ type source layers 60, and the p+ type contact layers 70 are referred to as active region. The active region is a region to which an electric current flows when the semiconductor apparatus 1000, which is an MOSFET, is switched on.

Note that the p+ type contact layers 70 are provided to come into ohmic contact with a source electrode 100 described below to stabilize the potential of the p type base layers 50 at 0 V that is the same potential as the potential of the source electrode 100. If the potential of the p type base layers 50 is not stable, a voltage applied to regions of a gate oxide film 120 sandwiched between the p type base layers 50 and a gate electrode 110 fluctuates and an ON characteristic at the switching time fluctuates. The p+ type contact layers 70 suppress the fluctuation.

P contact holes 90a are positioned in regions of the n+ type source layers 60 covered with the p+ type contact layers 70. Further, n contact holes 90b are positioned in regions of the n+ type source layers 60 not covered with the p+ type contact layers 70. That is, the p contact holes 90a and the n contact holes 90b are separated by an interlayer insulating film 130 described below.

Openings of the p contact holes 90a and openings of the n contact holes 90b are rectangles having the same shape and the same size. The p contact holes 90a and the n contact holes 90b are alternately positioned at fixed intervals in the first direction 2 in plan view such that the centers of the p contact holes 90a and the n contact holes 90b overlap the centers of the width in the second direction 4 of the n+ type source layers 60. The area of the n contact holes 90b in the entire active region is smaller than the area in the case in which the n contact holes 90b are not separated by the interlayer insulating film 130 described below.

Note that, here, an example in which the shape of the openings of the p contact holes 90a and the opening of the n contact holes 90b is the rectangle is described. However, the shape of the openings is not limited to this and may be a circle or an ellipse. When the shape of the openings of the p contact holes 90a and the openings of the n contact holes 90b is the rectangle, all of the lengths in the first direction 2 and the lengths in the second direction 4 of the p contact holes 90a and the n contact holes 90b may be equal. Alternatively, in the case described above, the width in the first direction 2 of the n contact holes 90b may be smaller than the width in the first direction 2 of the p contact holes 90a. Accordingly, the area of the n contact holes 90b may be set smaller than the area in the case in which the n contact holes 90b are not separated by the interlayer insulating film 130 described below.

Further, the intervals of the n contact holes 90b and the p contact holes 90a may be increased to reduce the number of the n contact holes 90b in the entire semiconductor apparatus 1000.

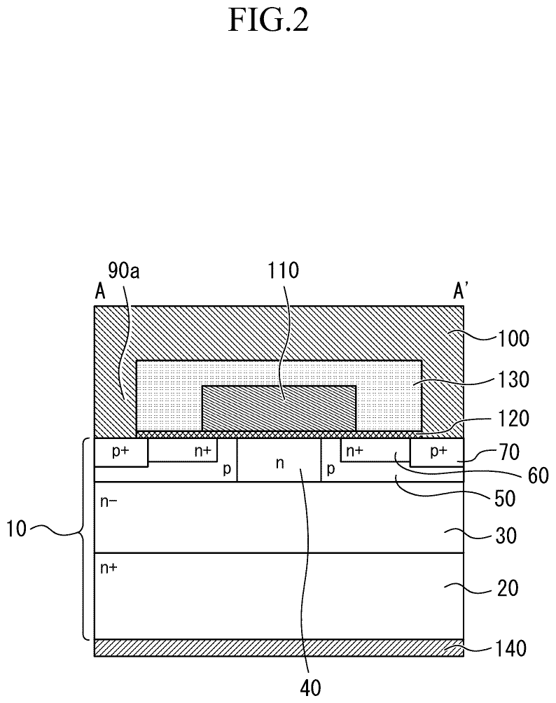

FIG. 2 is a sectional view taken along A-A′ in FIG. 1. Note that, in FIG. 2, for convenience of description, the passivation film is not illustrated. The same applies in sectional views taken along A-A′ referred to below.

The semiconductor apparatus 1000 includes a semiconductor substrate 10. The semiconductor substrate 10 may be formed from a wide band gap semiconductor. The wide band gap semiconductor is, for example, silicon carbide, a gallium nitride-based material, or diamond.

The semiconductor substrate 10 includes an n+ type substrate layer 20. The n+ type substrate layer 20 is formed by silicon carbide. A drain electrode 140 is connected to the lower surface side of the n+ type substrate layer 20. An n-type drift layer 30 is connected to the upper surface side of the n+ type substrate layer 20.

The n type base layer 40 is provided on the upper surface side of the n-type drift layer 30. The p type base layers 50 are provided on both sides of the n type base layer 40. That is, the n type base layer 40 and the p type base layers 50 are provided side by side each other on the upper surface side of the n-type drift layer 30.

The n+ type source layers 60 are selectively provided on the upper surface side of the p type base layers 50. The n+ type source layers 60 are source layers having higher impurity concentration than the n type base layer 40. The p+ type contact layers 70 are selectively provided on the upper surface side of the p type base layers 50 and a side of the n+ type source layers 60 not connected to the p type base layers 50. The p+ type contact layers 70 are contact layers having higher impurity concentration than the p type base layers 50.

In other words, the p type base layers 50 are thicker than the n+ type source layers 60 and the p+ type contact layers 70. The p+ type contact layers 70 are thicker than the n+ type source layers 60. Further, the thickness of the n type base layer 40 may be equal to, for example, the thickness of the p type base layers 50.

The gate oxide film 120 is provided on the n type base layer 40, the p type base layers 50, the n+ type source layers 60, and the p+ type contact layers 70. The gate electrode 110 is provided on the gate oxide film 120.

The upper surfaces of the gate electrode 110 and the gate oxide film 120 are covered with the interlayer insulating film 130. The upper surfaces of the interlayer insulating film 130 and the p+ type contact layers 70 are covered with the source electrode 100.

The plurality of p contact holes 90a illustrated in FIG. 1 are provided to expose parts of the p+ type contact layers 70 from the interlayer insulating film 130 as illustrated in FIG. 2. That is, the p+ type contact layers 70 and the source electrode 100 are electrically connected by the p contact holes 90a.

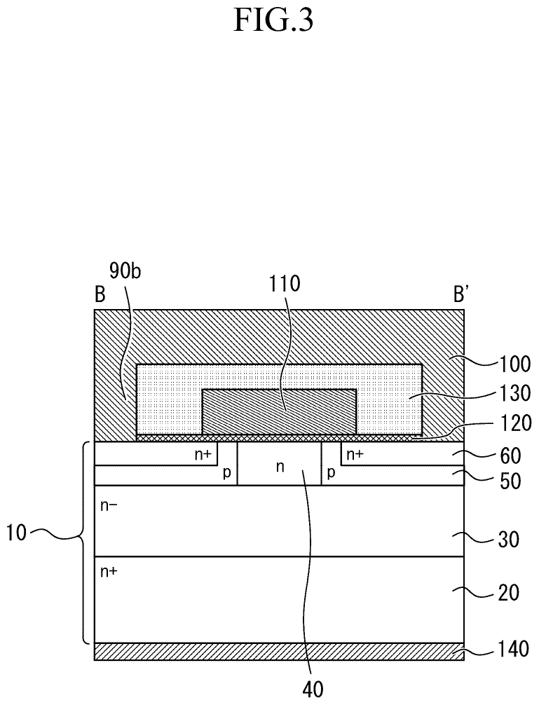

FIG. 3 is a sectional view taken along B-B′ in FIG. 1. Note that, in FIG. 3, for convenience of description, the passivation film is not illustrated. The same applies in sectional views taken along B-B′ referred to below.

The sectional view of FIG. 3 is different from the sectional view of FIG. 2 in that the sectional view does not pass the p+ type contact layers 70. For that reason, only portions having configurations different from the configurations illustrated in the sectional view of FIG. 2 are described and description of the other portions is omitted.

The n+ type source layers 60 are selectively provided on the upper surface side of the p type base layers 50. That is, the p type base layers 50 are thicker than the n+ type source layers 60.

The gate oxide film 120 is provided on the n type base layer 40, the p type base layers 50, and the n+ type source layers 60. The upper surfaces of the interlayer insulating film 130 and the n+ type source layers 60 are covered with the source electrode 100.

The n contact holes 90b illustrated in FIG. 1 are provided to expose the n+ type source layers 60 from the interlayer insulating film 130 as illustrated in FIG. 3. That is, the n+ type source layers 60 and the source electrode 100 are electrically connected by the n contact holes 90b.

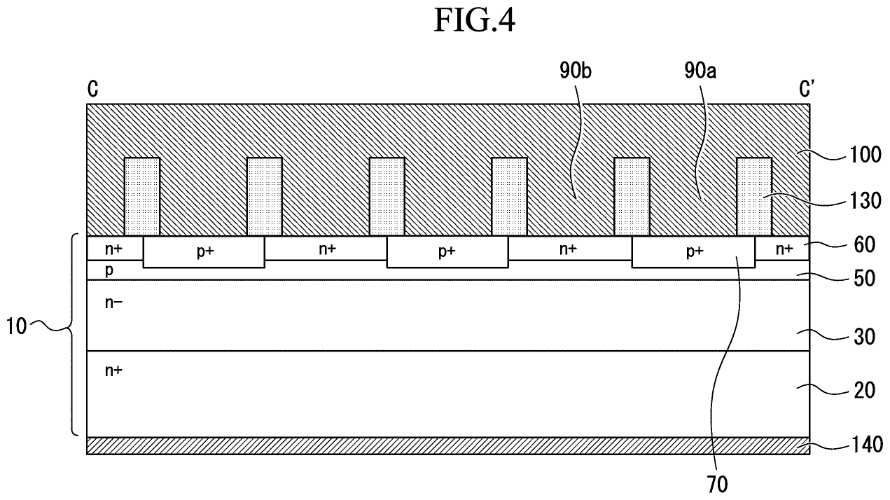

FIG. 4 is a sectional view taken along C-C′ in FIG. 1. Note that, in FIG. 4, for convenience of description, the passivation film is not illustrated. The same applies in sectional views taken along C-C′ referred to below.

The semiconductor apparatus 1000 includes the semiconductor substrate 10. The semiconductor substrate 10 includes the n+ type substrate layer 20. The drain electrode 140 is connected to the lower surface side of the n+ type substrate layer 20. The n-type drift layer 30 is connected to the upper surface side of the n+ type substrate layer 20.

The p type base layers 50 are provided on the upper surface side of the n-type drift layer 30. The n+ type source layers 60 and the p+ type contact layers 70 are alternately provided on the upper surface side of the p type base layers 50. The upper surfaces of the boundaries between the n+ type source layers 60 and the p+ type contact layers 70 are covered with the interlayer insulating film 130. The interlayer insulating film 130, the upper surfaces of the n+ type source layers 60, and the upper surfaces of the p+ type contact layers 70 are covered with the source electrode 100.

As illustrated in FIG. 2 as well, the p+ type contact layers 70 and the source electrode 100 are electrically connected by the p contact holes 90a. As illustrated in FIG. 3 as well, the n+ type source layers 60 and the source electrode 100 are electrically connected by the n contact holes 90b.

Further, the area of the n+ type source layers 60 connected to the source electrode 100 by the plurality of n contact holes 90b is smaller than the area in the case in which the n contact holes 90b are not separated by the interlayer insulating film 130.

Subsequently, a method of manufacturing a semiconductor apparatus according to the present embodiment is described. Here, a method of manufacturing the semiconductor apparatus 1000 is described. However, basic configurations of methods of manufacturing semiconductor apparatuses according to the present disclosure are the same. The methods of manufacturing the semiconductor apparatuses according to the embodiments are indicated by sizes of components or types of injected ions in the method of manufacturing the semiconductor apparatus 1000 being replaced to correspond to substituting components.

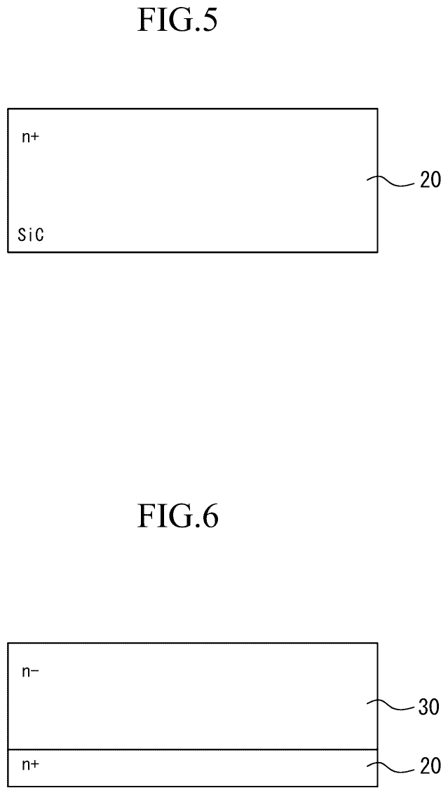

FIG. 5 is a first diagram illustrating a process for manufacturing a semiconductor apparatus according to the first embodiment of the present disclosure. The semiconductor apparatus 1000 is formed on the n+ type substrate layer 20.

In the following description, in figures illustrating a process for manufacturing the semiconductor apparatus 1000, a sectional structure corresponding to the sectional view taken along A-A′ in FIG. 1 is illustrated.

FIG. 6 is a second diagram illustrating the process for manufacturing the semiconductor apparatus according to the first embodiment of the present disclosure. Here, the n-type drift layer 30 is formed by, for example, epitaxial growth on the upper surface of the n+ type substrate layer 20.

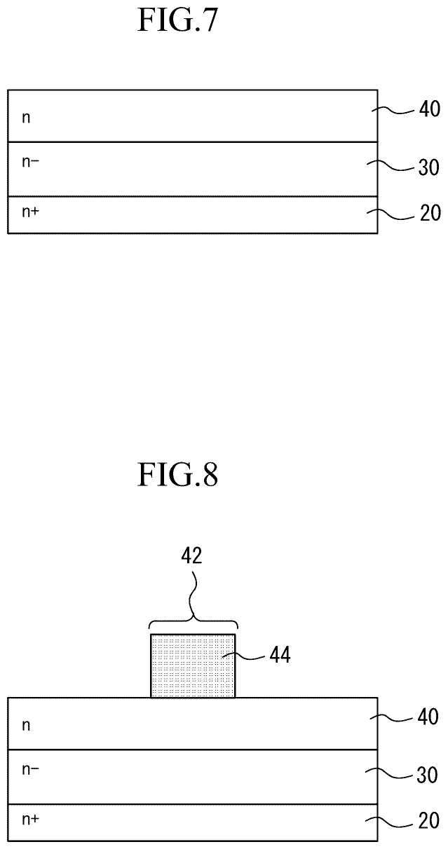

FIG. 7 is a third diagram illustrating the process for manufacturing the semiconductor apparatus according to the first embodiment of the present disclosure. Here, the n type base layer 40 is formed by ion-implanting n type impurities such as N to the upper surface side of the n-type drift layer 30. The n type base layer 40 may be selectively formed in a part of the upper surface of the n-type drift layer 30 by using, for example, a photomask or may be formed over the entire upper surface of the n-type drift layer 30 by not using the photomask.

FIG. 8 is a fourth diagram illustrating the process for manufacturing the semiconductor apparatus according to the first embodiment of the present disclosure. A first mask 42 is formed such that portions corresponding to formation regions of the p type base layers 50 are opened on the upper surface side of the n type base layer 40. The first mask 42 is formed by, for example, film formation of a thin film 44 like a CVD film, photolithography, and dry etching.

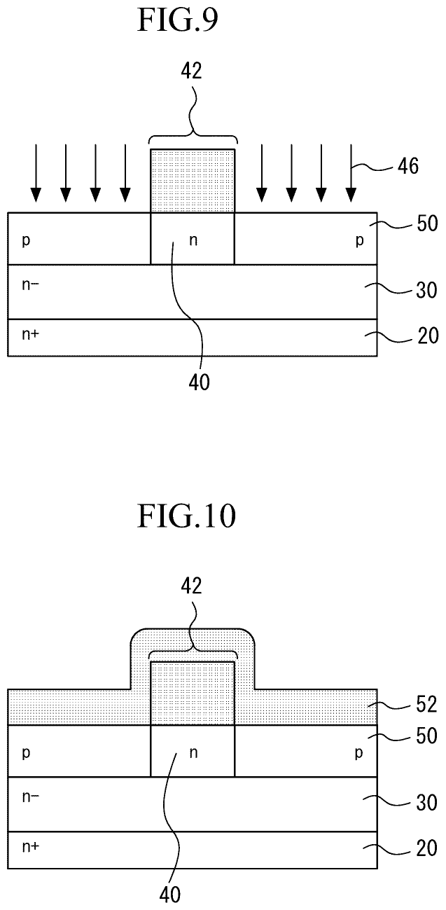

FIG. 9 is a fifth diagram illustrating the process for manufacturing the semiconductor apparatus according to the first embodiment of the present disclosure. Here, the p type base layers 50 provided side by side with the n type base layer 40 on the upper surface side of the n-type drift layer 30 are formed by ion-implanting p type impurities such as Al to the upper surface side of the n type base layer 40. Note that, in the ion implantation, n type impurities such as N may be shallowly implanted.

According to the ion implantation described above, a region covered with the first mask 42 is maintained as the n type base layer 40 and the p type base layers 50 are formed in regions not covered with the first mask 42. That is, the outermost surface of a channel region of a finally obtained semiconductor apparatus 1000 is formed as the n type base layer 40. As a result, since a channel is easily induced, a threshold voltage can be reduced.

FIG. 10 is a sixth diagram illustrating the process for manufacturing the semiconductor apparatus according to the first embodiment of the present disclosure. Here, a thin film 52 is formed on the upper surface and the sidewalls of the first mask 42 and the upper surfaces of the p type base layers 50. The thin film 52 is, for example, a CVD film.

FIG. 11 is a seventh diagram illustrating the process for manufacturing the semiconductor apparatus according to the first embodiment of the present disclosure. Here, the second mask 54 including the first mask 42 is formed by etching the thin film 52. Specifically, the thin film 52 is etched until spacers 52a are formed on the sidewalls of the first mask 42. The etching is implemented by, in anisotropic etching such as dry etching, using a condition substantially without etching in the sidewall direction of the first mask 42.

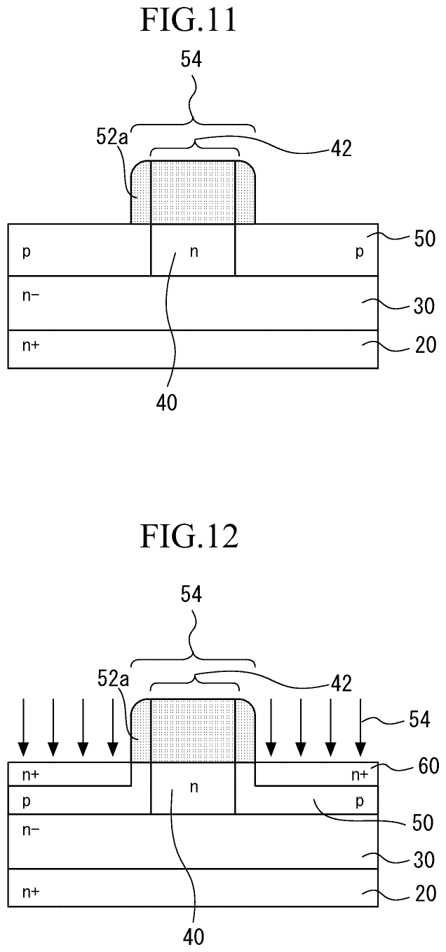

FIG. 12 is an eighth diagram illustrating the process for manufacturing the semiconductor apparatus according to the first embodiment of the present disclosure. Here, the n+ type source layers 60 selectively provided on the upper surface side of the p type base layers 50 are formed by ion-implanting n type impurities such as N to the upper surface side of the p type base layers 50 and the second mask 54.

In the ion implantation described above, the region covered with the second mask 54 is maintained and the n+ type source layers 60 are formed in the regions not covered with the second mask 54. The second mask 54 is formed in a self-alignment manner with the first mask 42. For that reason, deviation does not occur in alignment of the p type base layers 50 and the n+ type source layers 60 and the length of the channel region does not fluctuate. As a result, fluctuation in the threshold voltage due to the deviation of the alignment can be eliminated. That is, the semiconductor apparatus 1000 according to the present embodiment can improve the short circuit tolerance itself and, in addition, suppress variation in the short circuit tolerance.

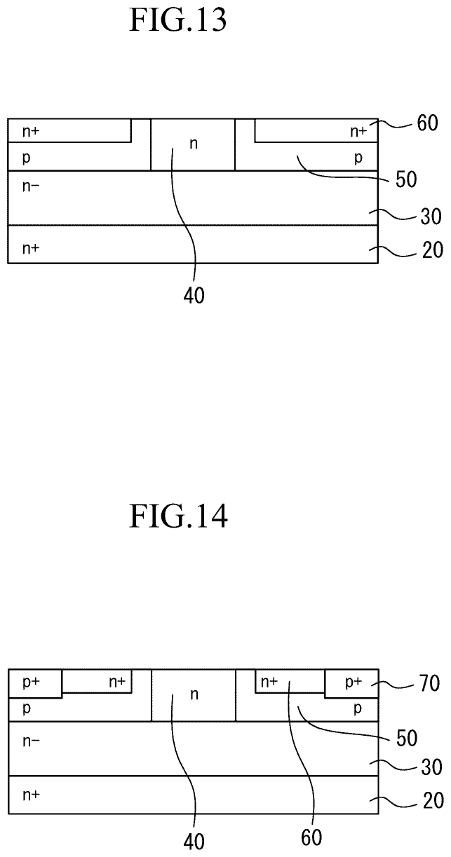

FIG. 13 is a ninth diagram illustrating the process for manufacturing the semiconductor apparatus according to the first embodiment of the present disclosure. Here, the second mask 54 is removed by wet etching using, for example, HF.

FIG. 14 is a tenth diagram illustrating the process for manufacturing the semiconductor apparatus according to the first embodiment of the present disclosure. Here, the p+ type contact layers 70 selectively provided on the upper surface side of the p type base layers 50 are formed by ion-implanting p type impurities such as Al to the upper surface side of the n+ type source layers 60.

The ion implantation described above is performed after a mask in which portions corresponding to the formation regions of the p+ type contact layers 70 are opened is formed. When ion implantation in a high temperature state is performed in order to increase implantation dosage, the mask may be formed by, for example, film formation of a CVD film, photolithography, and dry etching. When ion implantation in a normal temperature state is performed, the mask may be formed by, for example, a photomask. The mask formed before the ion implantation is removed by wet etching using, for example, HF after the ion implantation is completed.

Subsequently, the gate oxide film 120 is formed on the n type base layer 40, the p type base layers 50, the n+ type source layers 60, and the p+ type contact layers 70 by a general method. Subsequently, the gate electrode 110 is formed on the gate oxide film 120 by the general method. Subsequently, the interlayer insulating film 130 provided on the semiconductor substrate 10 to cover the gate oxide film 120 and the gate electrode 110 and including the plurality of n contact holes 90b that expose parts of the n+ type source layers 60 and the plurality of p contact holes 90a that expose parts of the p+ type contact layers 70 is formed by the general method.

Subsequently, the source electrode 100 connected to the n+ type source layers 60 via the n contact holes 90b and connected to the p+ type contact layers 70 via the p contact holes 90a is formed by the general method. The drain electrode 140 is formed on the lower surface side of the n-type drift layer 30 by the general method. Further, a passivation film or the like may be formed by the general method. The semiconductor apparatus 1000 is formed by the process described above.

Effects shown by the semiconductor apparatus 1000 according to the present embodiment are described. Contact holes of the semiconductor apparatus of the related art simultaneously expose the p+ type contact layers 70 and the n+ type source layers 60. That is, both of the p+ type contact layers 70 and the n+ type source layers 60 are electrically connected to the source electrode 100.

On the other hand, in the semiconductor apparatus 1000 according to the present embodiment, the p contact holes 90a to which the p+ type contact layers 70 and the source electrode 100 are electrically connected and the n contact holes 90b to which the n+ type source layers 60 and the source electrode 100 are electrically connected are respectively formed.

If the area of the n contact holes 90b is reduced, contact resistance in a current path between the drain electrode 140 and the source electrode 100 becomes negligibly large. That is, a voltage drop occurs between the source electrode 100 and a layer adjacent thereto. Specifically, a potential difference occurs between the source electrode 100 and the n+ type source layers 60.

Here, in the semiconductor apparatus 1000 according to the present embodiment, the area of the n contact holes 90b in the entire active region is set smaller than the area in the case in which the n contact holes 90b are not separated by the interlayer insulating film 130. That is, the area of the n+ type source layers 60 connected to the source electrode 100 by the n contact holes 90b is set to be smaller than the area in the case in which the n contact holes 90b are not separated by the interlayer insulating film 130.

As a result, a voltage drop between the source electrode 100 and the n+ type source layers 60 can be set larger than the voltage drop in the case in which the n contact holes 90b are not separated by the interlayer insulating film 130. Here, the potential of the p+ type contact layers 70 is the same potential as the potential of the p type base layers 50. That is, the potential of the n+ type source layers 60 can be set higher than the potential of the p type base layers 50 by the voltage drop between the source electrode 100 and the n+ type source layers 60.

If the potential of the n+ type source layers 60 is set higher than the potential of the p type base layers 50, a substrate bias effect can be generated. The substrate bias effect is an effect that reversal less easily occurs. More specifically, first, when the potential of the n+ type source layers 60 becomes higher than the potential of the p type base layers 50, since reverse bias is applied to PN junction formed by the n+ type source layers 60 and the p type base layers 50, depletion layers broaden. As a result, a negative fixed charge is generated in the depletion layers of the p type base layers 50 and a positive charge generated at the time of switching-on is neutralized. That is, reversal less easily occurs.

The substrate bias effect caused by the potential difference between the n+ type source layers 60 and the p type base layers 50 changes according to a value of an electric current flowing to the n+ type source layers 60. The change increases as a larger current flows. As a result, an effect of lowering an effective gate voltage increases. That is, although the substrate bias effect at a normal time is small, an effect at an abnormal time when an overcurrent flows such as a short circuit time is high. For that reason, it is possible to effectively reduce a short circuit current without seriously affecting a loss and the like at the normal time.

The semiconductor apparatus 1000 according to the present embodiment is the planar type MOSFET. The planar type MOSFET needs to perform cell pitch shrink when channel density is increased for characteristic improvement. In the cell pitch shrink, the length direction of the channel length 6 and a direction of the shrinking are the same direction. For that reason, when the cell pitch shrink is performed, the channel length 6 needs to be reduced.

However, the threshold voltage decreases when the channel length 6 is reduced. Since a saturation current increases according to the decrease in the threshold voltage, a problem in that the short circuit tolerance decreases occurs. For that reason, in the planar type MOSFET, in order to supplement the problem caused by reducing the channel length 6, the short circuit tolerance needs to be improved by a method that does not hinder the cell pitch shrink.

The semiconductor apparatus 1000 according to the present embodiment is capable of improving the short circuit tolerance without hindering the cell pitch shrink. That is, the semiconductor apparatus 1000 according to the present embodiment can achieve both of characteristic improvement by the cell pitch shrink and an increase in the short circuit tolerance in the planar type MOSFET.

Note that, when the cell pitch shrink is performed in a trench type MOSFET, the length direction of a channel length and a direction of the shrinking are different. For that reason, in the trench type MOSFET, it is unnecessary to reduce the channel length when the cell pitch shrink is performed. That is, the semiconductor apparatus 1000 according to the present embodiment shows a particularly high effect in the planar type MOSFET.

As described above, in the semiconductor apparatus 1000 according to the present embodiment, the area of the n+ type source layers 60 connected to the source electrode 100 by the n contact holes 90b is set to be smaller than the area in the case in which the n contact holes 90b are not separated by the interlayer insulating film 130. As a result, it is possible to improve the short circuit tolerance.

In the present embodiment, the openings of the p contact holes 90a and the openings of the n contact holes 90b have the same shape and the same size. The p contact holes 90a and the n contact holes 90b are alternately periodically positioned in the first direction 2 in plan view. As a result, in a process for manufacturing the semiconductor apparatus 1000, dimension variation in a chip or in a wafer can be suppressed. Therefore, it is possible to implement stable dimension control.

Further, as a modification of the present embodiment, the area of the n contact holes 90b in the entire active region is reduced. For example, it is conceivable to set the width in the first direction 2 of the n contact holes 90b smaller than the width in the first direction 2 of the p contact holes 90a. According to this change, it is possible to further improve the short circuit tolerance.

### Second Embodiment

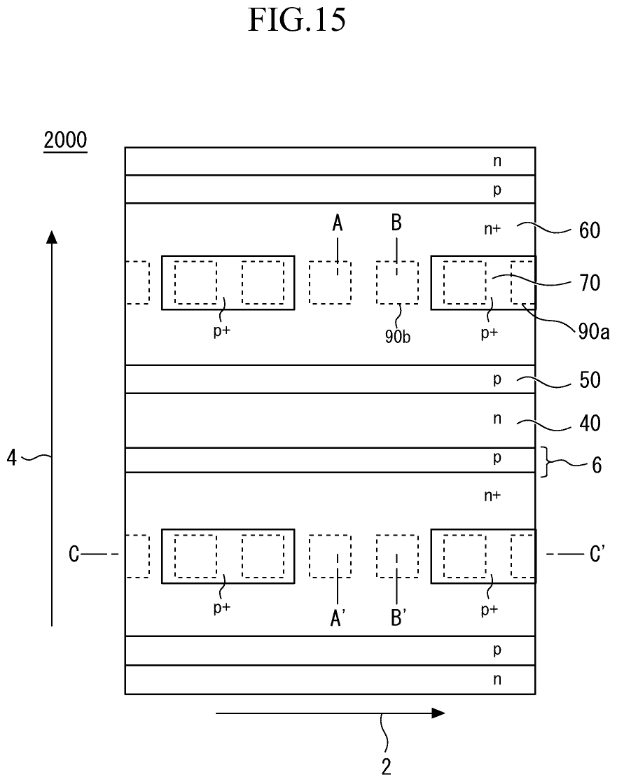

FIG. 15 is a plan view illustrating a configuration of a semiconductor apparatus according to a second embodiment of the present disclosure. FIG. 15 illustrates a plane layout of a cell region of a semiconductor apparatus 2000 that is a planar type MOSFET. The semiconductor apparatus 2000 is different from the semiconductor apparatus 1000 in that the p+ type contact layers 70 are longer in the first direction 2 and the p contact holes 90a and the n contact holes 90b are alternately positioned two by two.

The openings of the p contact holes 90a and the openings of the n contact holes 90b are rectangles having the same shape and the same size. The p contact holes 90a and the n contact holes 90b are alternately positioned two by two at fixed intervals in the first direction 2 in plan view such that the centers of the p contact holes 90a and the n contact holes 90b overlap the centers of the width in the second direction 4 of the n+ type source layers 60. The area of the n contact holes 90b in the entire active region is smaller than the area of the p contact holes 90a in the entire active region.

Note that, in the above description, the n contact holes 90b and the p contact holes 90a are alternately positioned two by two at the fixed intervals in the first direction 2 in plan view. However, the n contact holes 90b and the p contact holes 90a are not limited to this and, for example, may be periodically positioned.

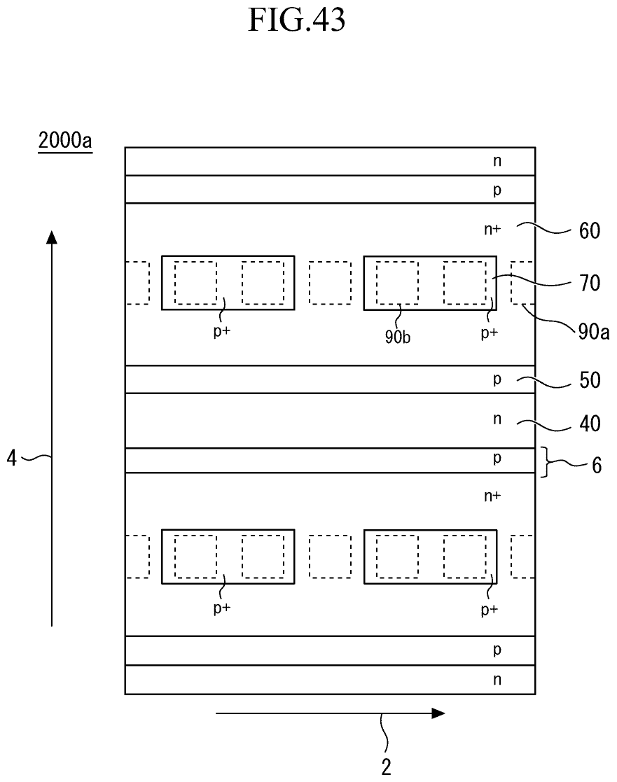

An example in which the openings of the n contact holes 90b and the openings of the p contact holes 90a are periodically positioned is described. FIG. 43 is a plan view illustrating a configuration of a semiconductor apparatus according to a first modification of the second embodiment of the present disclosure. In a semiconductor apparatus 2000a, an opening of one n contact hole 90b and openings of two p contact holes 90a are alternately positioned at fixed intervals in the first direction 2 in plan view.

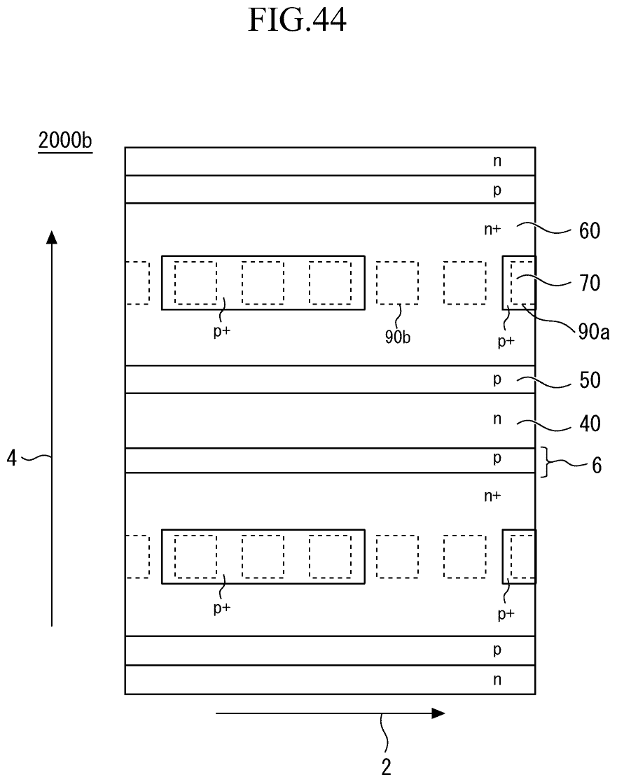

FIG. 44 is a plan view illustrating a configuration of a semiconductor apparatus according to a second modification of the second embodiment of the present disclosure. In a semiconductor apparatus 2000b, openings of two n contact holes 90b and openings of three p contact holes 90a are alternately positioned at fixed intervals in the first direction 2 in plan view.

Here, m pieces of n contact holes 90b positioned at fixed intervals in the first direction 2 are represented as a first contact hole group and n pieces of p contact holes 90a positioned at fixed intervals in the first direction 2 are represented as a second contact hole group. In this case, the semiconductor apparatus according to the present embodiment is a semiconductor apparatus in which the first contact hole group and the second contact hole group are positioned at fixed intervals in the first direction 2. Note that m is a value of 1 or more and n or less. According to this aspect, it is possible to set the area of the n contact holes 90b to be further smaller than the area in the case in which the n contact holes 90b are not separated by the interlayer insulating film 130.

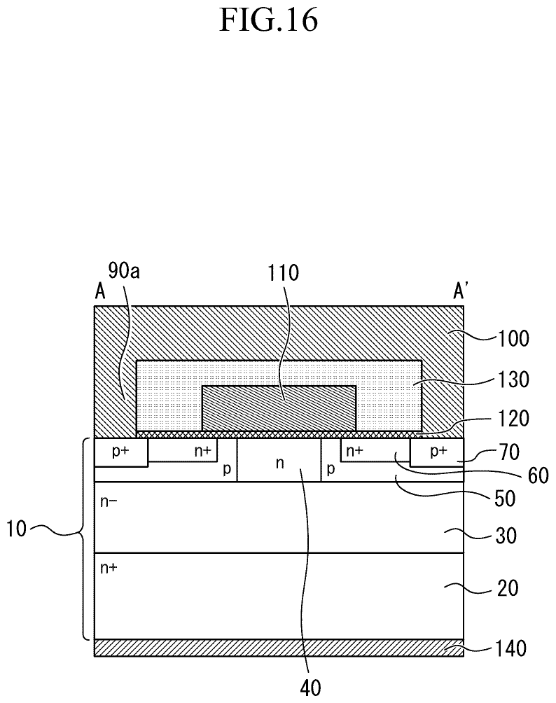

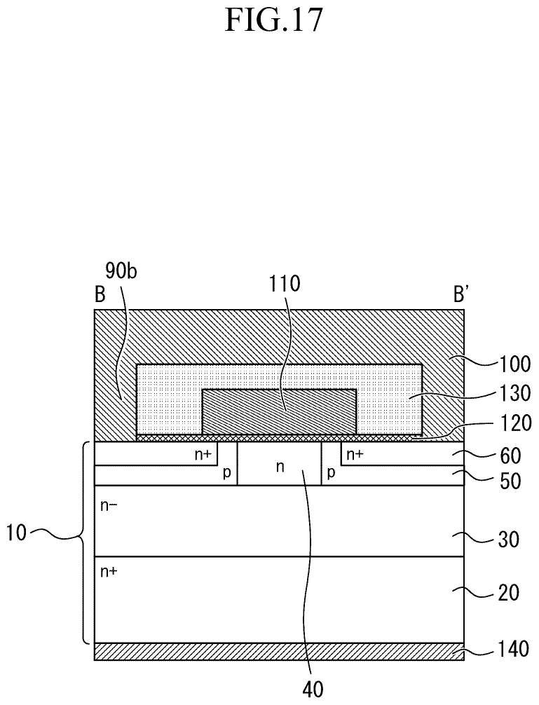

FIG. 16 is a sectional view taken along A-A′ in FIG. 15. Since FIG. 16 is the same figure as FIG. 2, description of FIG. 16 is omitted.

FIG. 17 is a sectional view taken along B-B′ in FIG. 15. Since FIG. 17 is the same figure as FIG. 3, description of FIG. 17 is omitted.

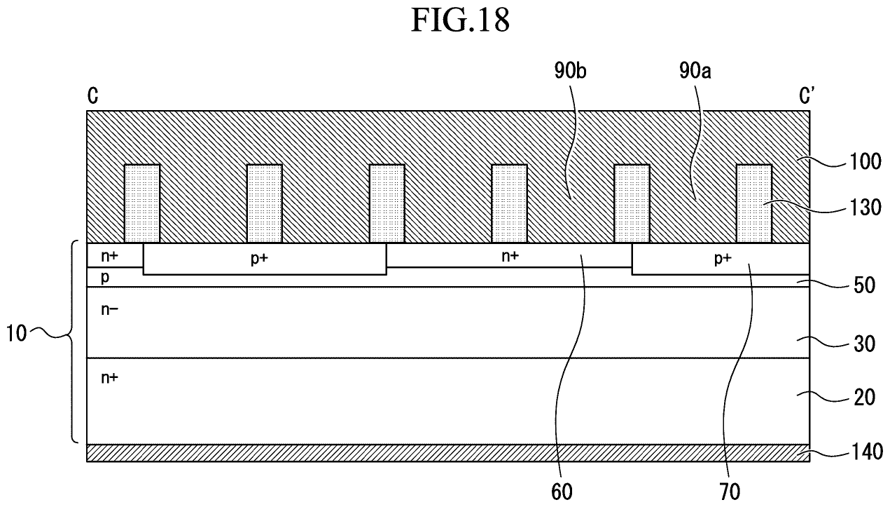

FIG. 18 is a sectional view taken along C-C′ in FIG. 15. FIG. 18 is different from FIG. 4 in that the n+ type source layers 60 and the p+ type contact layers 70 are longer in the first direction 2.

As described above, in the semiconductor apparatus 2000 according to the present embodiment, the area of the n+ type source layers 60 connected to the source electrode 100 by the plurality of n contact holes 90b is set to be smaller than the area in the case in which the n contact holes 90b are not separated by the interlayer insulating film 130. As a result, it is possible to improve the short circuit tolerance.

In the semiconductor apparatus 2000 according to the present embodiment, the openings of the p contact holes 90a and the openings of the n contact holes 90b are rectangles having the same shape and the same size. The p contact holes 90a and the n contact holes 90b are alternately positioned two by two at fixed intervals in the first direction 2 in plan view. As a result, in the process for manufacturing the semiconductor apparatus 2000, dimension variation in a chip or in a wafer can be suppressed. Therefore, it is possible to implement stable dimension control.

### Third Embodiment

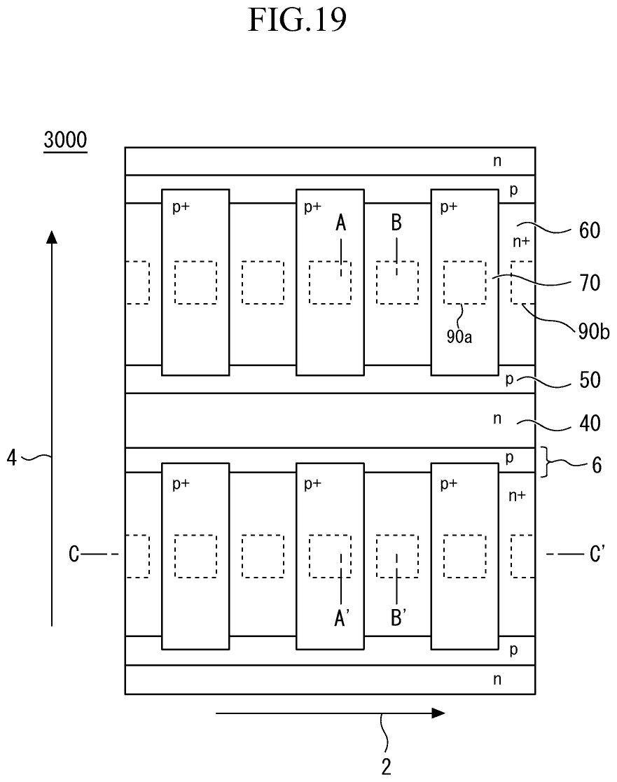

FIG. 19 is a plan view illustrating a configuration of a semiconductor apparatus according to a third embodiment of the present disclosure. FIG. 19 illustrates a plane layout of a cell region of a semiconductor apparatus 3000 that is a planar type MOSFET. The semiconductor apparatus 3000 is different from the semiconductor apparatus 1000 in that the p+ type contact layers 70 are longer in the second direction 4.

Parts of the n+ type source layers 60 and the p type base layers 50 are covered with the p+ type contact layers 70. The p+ type contact layers 70 are positioned in the first direction 2 to discretely cover the n+ type source layers 60 and the p type base layers 50. The length in the second direction 4 of the p+ type contact layers 70 is larger than the length in the second direction 4 of the n+ type source layers 60.

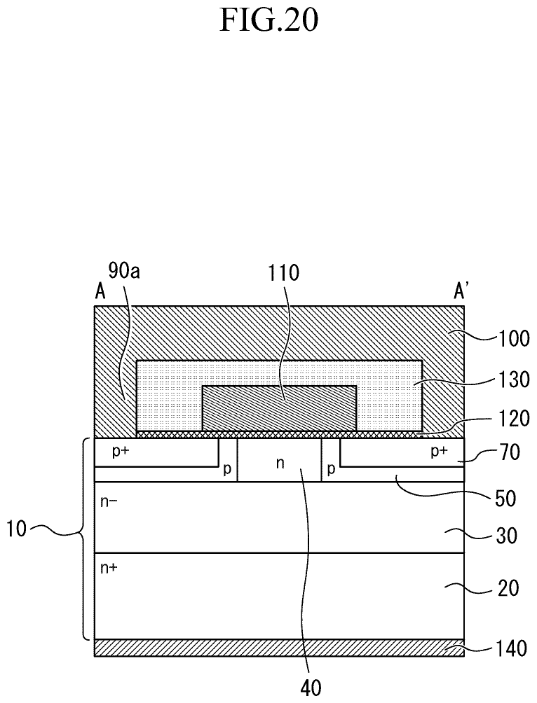

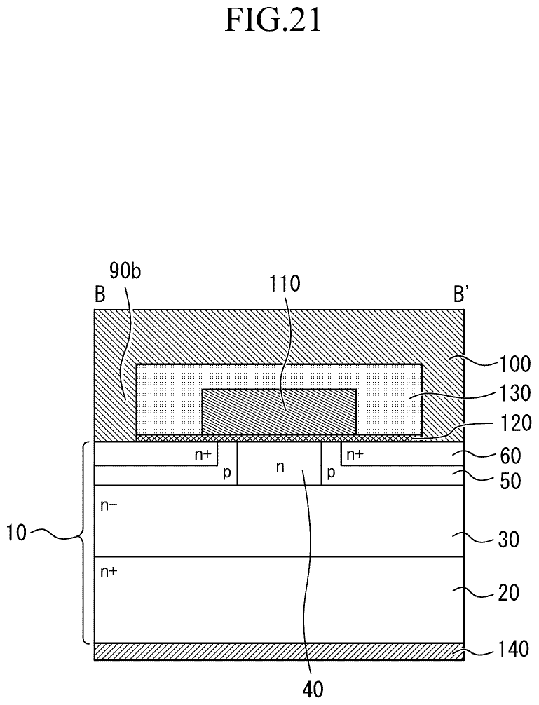

FIG. 20 is a sectional view taken along A-A′ in FIG. 19. FIG. 20 is different from FIG. 2 in that the semiconductor apparatus 3000 does not include the n+ type source layers 60.

The n type base layer 40 is provided on the upper surface side of the n-type drift layer 30. The p type base layers 50 are provided on both sides of the n type base layer 40. The p+ type contact layers 70 are selectively provided on the upper surface side of the p type base layers 50. That is, the p type base layers 50 are thicker than the p+ type contact layers 70. The gate oxide film 120 is provided on the n type base layer 40, the p type base layers 50, and the p+ type contact layers 70.

FIG. 21 is a sectional view taken along B-B′ in FIG. 19. Since FIG. 21 is the same figure as FIG. 3, description of FIG. 21 is omitted.

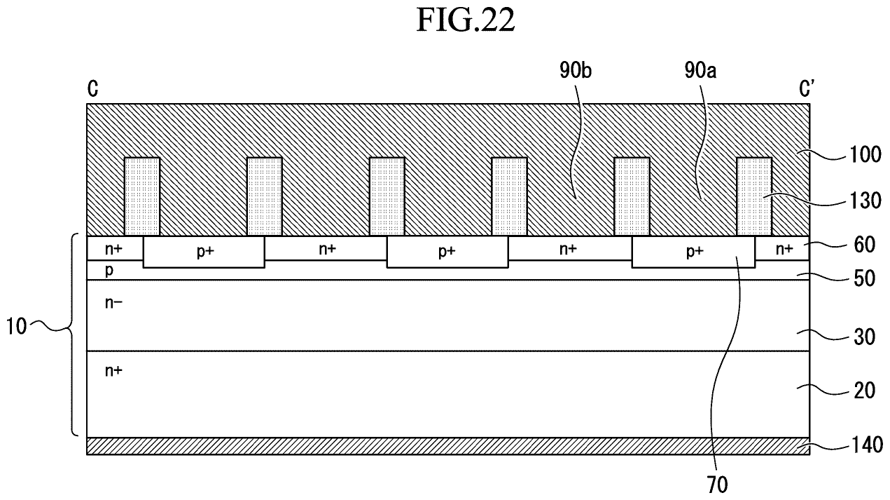

FIG. 22 is a sectional view taken along C-C′ in FIG. 19. Since FIG. 22 is the same figure as FIG. 4, description of FIG. 22 is omitted.

As described above, in the semiconductor apparatus 3000 according to the present embodiment, the area of the n+ type source layers 60 connected to the source electrode 100 by the n contact holes 90b is set to be smaller than the area in the case in which the n contact holes 90b are not separated by the interlayer insulating film 130. As a result, it is possible to improve the short circuit tolerance.

The semiconductor apparatus 3000 according to the present embodiment does not include the n+ type source layers 60 in the region illustrated in FIG. 20. That is, the semiconductor apparatus 3000 includes a region where the p type base layers 50 and the p+ type contact layers 70 are connected by only a path not via the n+ type source layers 60. In this region, a channel does not occur in a switching-on state. As a result, in the semiconductor apparatus 3000, since a channel region in the entire active region can be reduced, it is possible to reduce a saturation current and further improve the short circuit tolerance.

### Fourth Embodiment

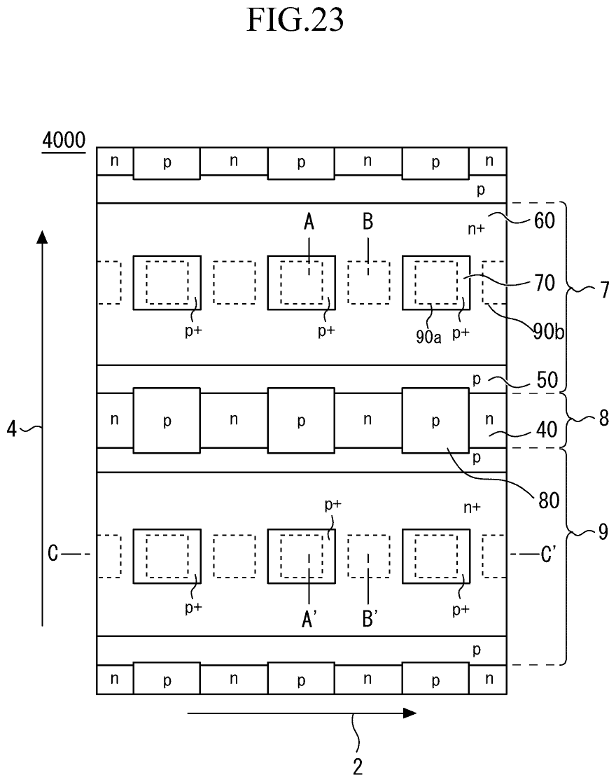

FIG. 23 is a plan view illustrating a configuration of a semiconductor apparatus according to a fourth embodiment of the present disclosure. FIG. 23 illustrates a plane layout of a cell region of a semiconductor apparatus 4000 that is a planar type MOSFET. The semiconductor apparatus 4000 is different from the semiconductor apparatus 1000 in that the semiconductor apparatus 4000 includes a JFET region 8.

The JFET region 8 is positioned between a first region 7 and a second region 9. The JFET region 8 includes the n type base layer 40 extending in the first direction 2. Parts of the n type base layer 40 are replaced with p type diffusion layers 80. Specifically, the p type diffusion layers 80 and the n type base layers 40 are alternately positioned at fixed intervals in the first direction 2 in plan view. The p type diffusion layers 80 and the p+ type contact layers 70 are alternately positioned at fixed intervals in the second direction 4 in plan view.

The p type diffusion layers 80 are positioned in the first direction 2 to discretely cover the n type base layers 40. The length in the second direction 4 of the p type diffusion layers 80 is larger than the width in the second direction 4 of the n type base layers 40. For that reason, the p type diffusion layers 80 are connected to the p type base layers 50.

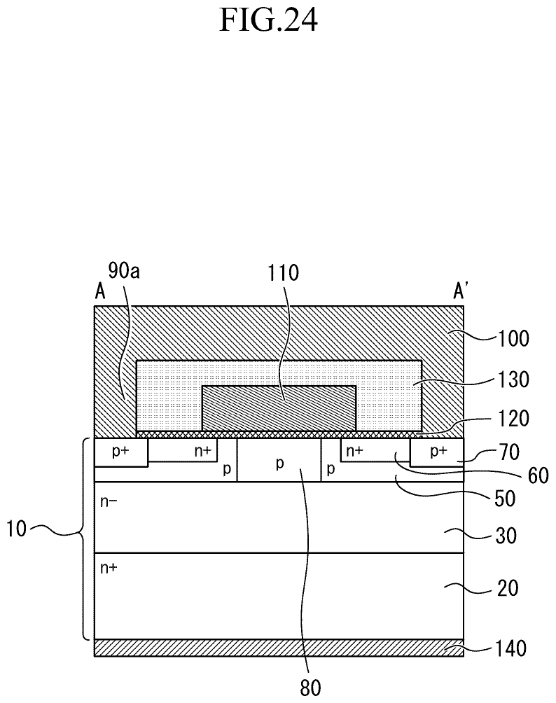

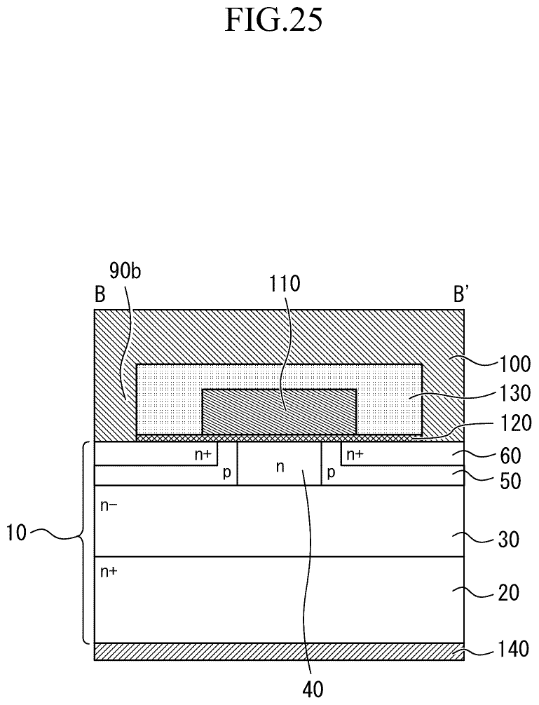

FIG. 24 is a sectional view taken along A-A′ in FIG. 23. FIG. 24 is different from FIG. 2 in that the semiconductor apparatus 4000 includes the p type diffusion layer 80 instead of the n type base layer 40.

The p type diffusion layer 80 is provided on the upper surface side of the n-type drift layer 30. The p type base layers 50 are provided on both sides of the p type diffusion layer 80. The gate oxide film 120 is provided on the p type diffusion layer 80, the p type base layers 50, the n+ type source layers 60, and the p+ type contact layers 70.

FIG. 25 is a sectional view taken along B-B′ in FIG. 23. Since FIG. 25 is the same figure as FIG. 3, description of FIG. 25 is omitted.

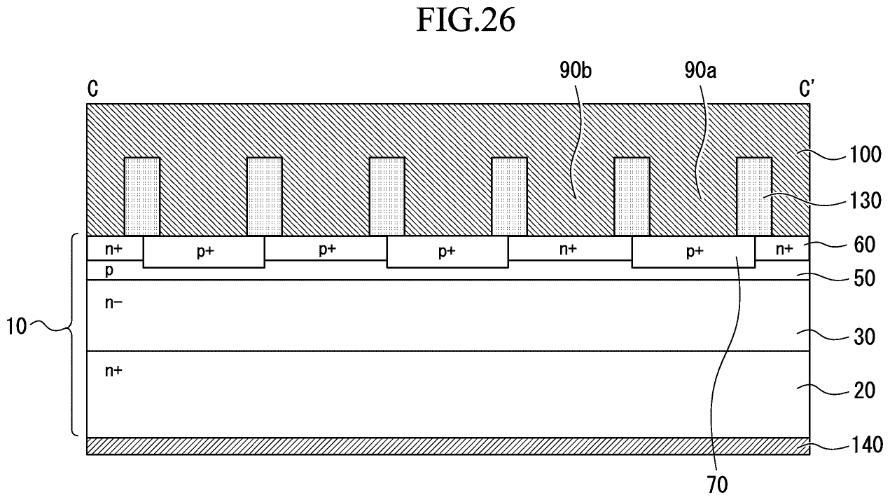

FIG. 26 is a sectional view taken along C-C′ in FIG. 23. FIG. 26 is different from FIG. 4 in that parts of the n+ type source layers 60 are replaced with the p+ type contact layers 70. As described above, in the semiconductor apparatus 4000 according to the present embodiment, the area of the n+ type source layers 60 connected to the source electrode 100 by the n contact holes 90b is set to be smaller than the area in the case in which the n contact holes 90b are not separated by the interlayer insulating film 130. As a result, it is possible to improve the short circuit tolerance.

The semiconductor apparatus 4000 according to the present embodiment does not include the n type base layer 40 in the region illustrated in FIG. 24. That is, the semiconductor apparatus 4000 includes a region where the p type base layers 50 and the n-type drift layer 30 are connected by only a path not via the n type base layer 40. In this region, a channel does not occur in a switching-on state. As a result, in the semiconductor apparatus 4000, since a channel region in the entire active region can be reduced, it is possible to reduce a saturation current and further improve the short circuit tolerance.

### Fifth Embodiment

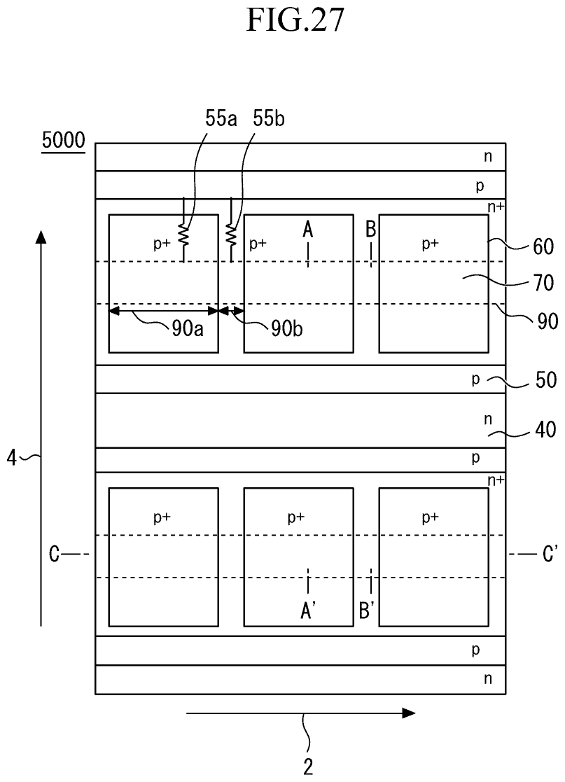

FIG. 27 is a plan view illustrating a configuration of a semiconductor apparatus according to a fifth embodiment of the present disclosure. FIG. 27 illustrates a plane layout of a cell region of a semiconductor apparatus 5000 that is a planar type MOSFET. The semiconductor apparatus 5000 is different from the semiconductor apparatus 1000 in that the area of the p+ type contact layers 70 is larger and the semiconductor apparatus 5000 includes contact holes 90 instead of the p contact holes 90a and the n contact holes 90b.

Parts of the n+ type source layers 60 are covered with the p+ type contact layers 70. The p+ type contact layers 70 are positioned at fixed intervals in the first direction 2 to discretely cover the n+ type source layers 60.

The contact holes 90 are positioned in the n+ type source layers 60. The contact holes 90 extend in the first direction 2 over regions covered with the p+ type contact layers 70 and regions not covered with the p+ type contact layers 70. That is, the contact holes 90 are configured by the p contact holes 90a and the n contact holes 90b alternately positioned in the first direction. The width in the second direction 4 of the contact holes 90 is smaller than, for example, the length in the second direction 4 of the p+ type contact layers 70.

The width in the first direction 2 of the openings of the n contact holes 90b is smaller than the width in the first direction 2 of the openings of the p contact holes 90a. For that reason, the area of the n+ type source layers 60 connected to the source electrode 100 by the contact holes 90 is smaller than the area of the p+ type contact layers 70 connected to the source electrode 100 by the contact holes 90.

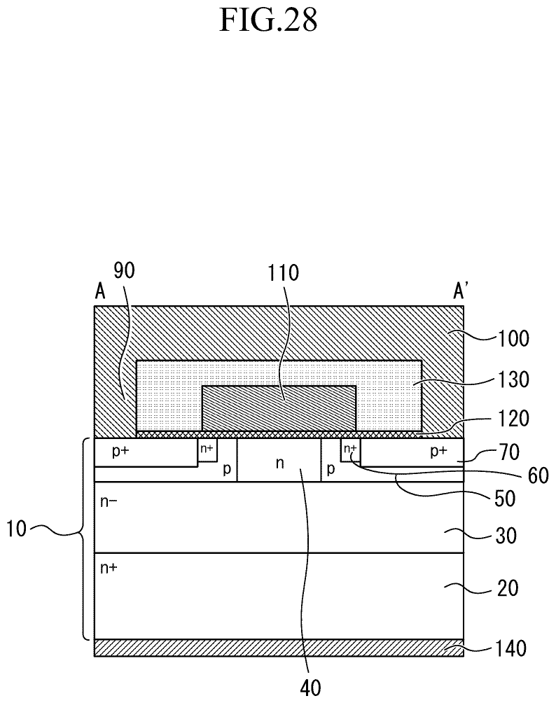

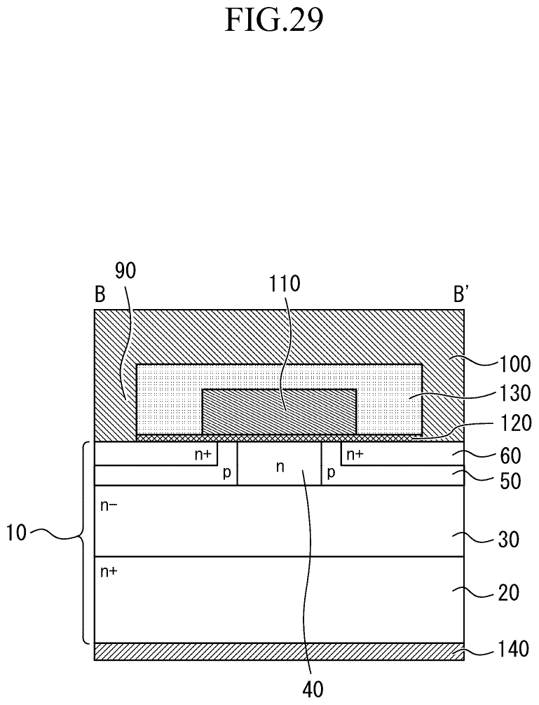

FIG. 28 is a sectional view taken along A-A′ in FIG. 27. FIG. 28 is different from FIG. 2 in that the semiconductor apparatus 5000 includes the contact holes 90 instead of the p contact holes 90a and the p+ type contact layers 70 are longer in the first direction 2.

FIG. 29 is a sectional view taken along B-B′ in FIG. 27. FIG. 29 is different from FIG. 3 in that the semiconductor apparatus 5000 includes the contact holes 90 instead of the n contact holes 90b.

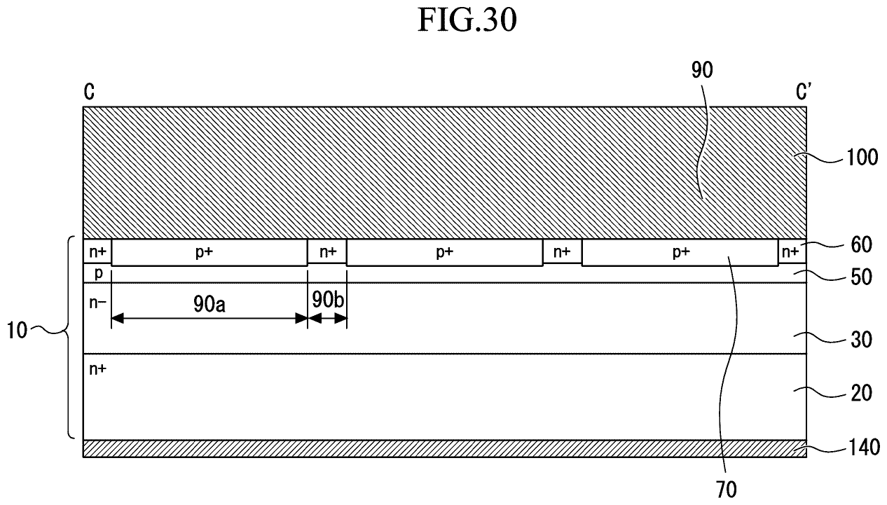

FIG. 30 is a sectional view taken along C-C′ in FIG. 27. FIG. 30 is different from FIG. 4 in that the lengths in the first direction 2 of the n+ type source layers 60 and the p+ type contact layers 70 are different and the semiconductor apparatus 5000 does not include the interlayer insulating film 130.

The p type base layers 50 are provided on the upper surface side of the n-type drift layer 30. The n+ type source layers 60 and the p+ type contact layers 70 are alternately provided on the upper surface side of the p type base layers 50. The upper surfaces of the n+ type source layers 60 and the upper surfaces of the p+ type contact layers 70 are covered with the source electrode 100.

Subsequently, effects shown by the semiconductor apparatus 5000 according to the present embodiment are described. In the semiconductor apparatus 5000 according to the present embodiment, the width in the first direction 2 of the n+ type source layers 60 connected to the source electrode 100 by the contact holes 90 is set smaller than the width in the first direction 2 of the p+ type contact layers 70 connected to the source electrode 100 by the contact holes 90. As a result, the potential of the n+ type source layers 60 can be set higher than the potential of the p type base layers 50 by a voltage drop between the source electrode 100 and the n+ type source layers 60 via the contact holes 90.

For that reason, the semiconductor apparatus 5000 according to the present embodiment shows the same effects as the effects described in the first embodiment. That is, in the semiconductor apparatus 5000 according to the present embodiment can improve the short circuit tolerance. The semiconductor apparatus 5000 according to the present embodiment can achieve both of characteristic improvement by the cell pitch shrink and an increase in the short circuit tolerance in the planar type MOSFET.

Further, in the present embodiment, the resistance in a path indicated by a resistor 55b is larger than the resistance in a path indicated by a resistor 55a. That is, in the present embodiment, it is possible to set a voltage drop in the path indicated by the resistor 55b larger than a voltage drop in the path indicated by the resistor 55a. As a result, it is possible to set the potential of the n+ type source layers 60 further higher than the potential of the p type base layers 50.

As described above, in the semiconductor apparatus 5000 according to the present embodiment, the width in the first direction 2 of the n+ type source layers 60 connected to the source electrode 100 by the contact holes 90 is set to be smaller than the width in the first direction 2 of the p+ type contact layers 70 connected to the source electrode 100 by the contact holes 90. As a result, it is possible to improve the short circuit tolerance.

### Sixth Embodiment

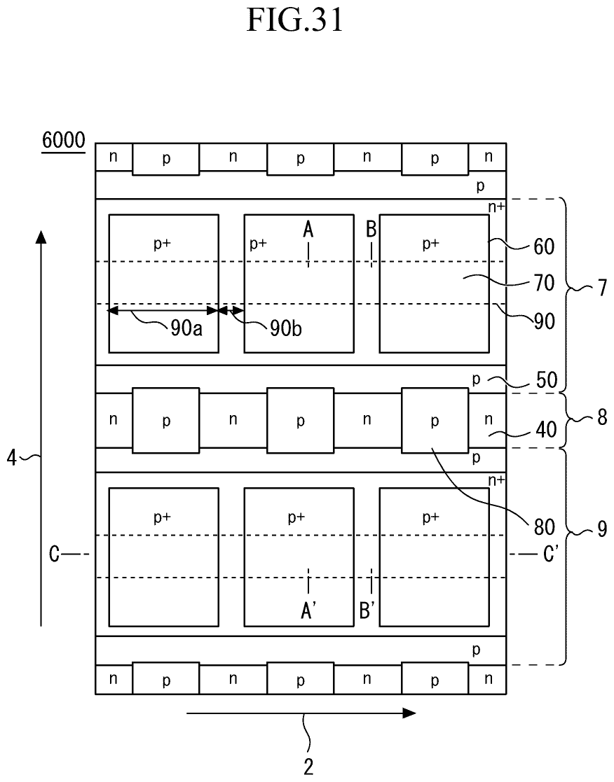

FIG. 31 is a plan view illustrating a configuration of a semiconductor apparatus according to a sixth embodiment of the present disclosure. FIG. 31 illustrates a plane layout of a cell region of a semiconductor apparatus 6000 that is a planar type MOSFET. The semiconductor apparatus 6000 is different from the semiconductor apparatus 5000 in that the semiconductor apparatus 6000 includes the JFET region 8.

The JFET region 8 is positioned between the first region 7 and the second region 9. The JFET region 8 includes the n type base layer 40 extending in the first direction 2. Parts of the n type base layer 40 are replaced with the p type diffusion layers 80. Specifically, the p type diffusion layers 80 and the n type base layers 40 are alternately positioned at fixed intervals in the first direction 2 in plan view. The p type diffusion layers 80 and the p+ type contact layers 70 are alternately positioned at fixed intervals in the second direction 4 in plan view.

The p type diffusion layers 80 are positioned in the first direction 2 to discretely cover the n type base layers 40. The length in the second direction 4 of the p type diffusion layers 80 is larger than the width in the second direction 4 of the n type base layers 40. For that reason, the p type diffusion layers 80 are connected to the p type base layers 50.

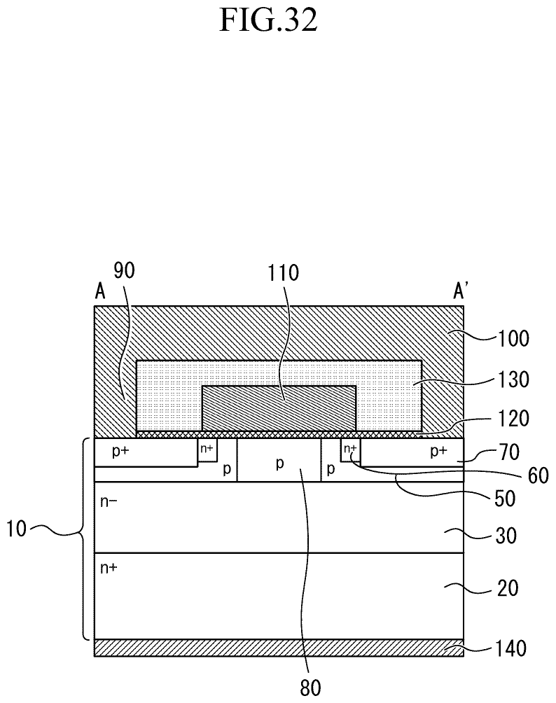

FIG. 32 is a sectional view taken along A-A′ in FIG. 31. FIG. 32 is different from FIG. 28 in that the semiconductor apparatus 6000 includes the p type diffusion layer 80 instead of the n type base layer 40.

The p type diffusion layer 80 is provided on the upper surface side of the n-type drift layer 30. The p type base layers 50 are provided on both sides of the p type diffusion layer 80. The gate oxide film 120 is provided on the p type diffusion layer 80, the p type base layers 50, the n+ type source layers 60, and the p+ type contact layers 70.

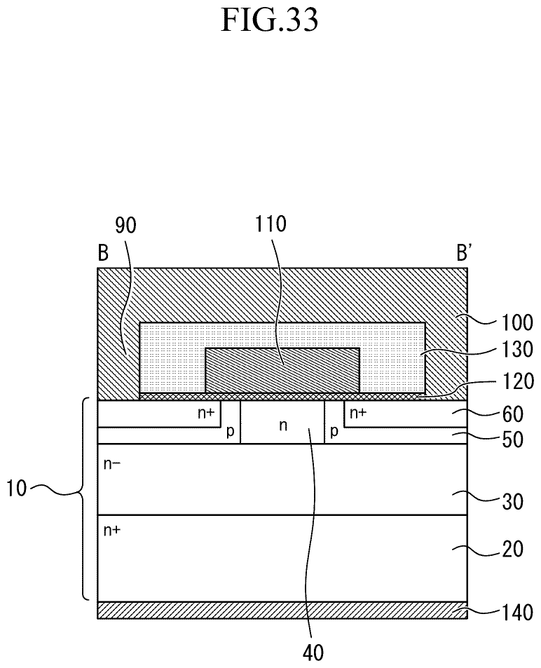

FIG. 33 is a sectional view taken along B-B′ in FIG. 31. Since FIG. 33 is the same figure as FIG. 29, description of FIG. 33 is omitted.

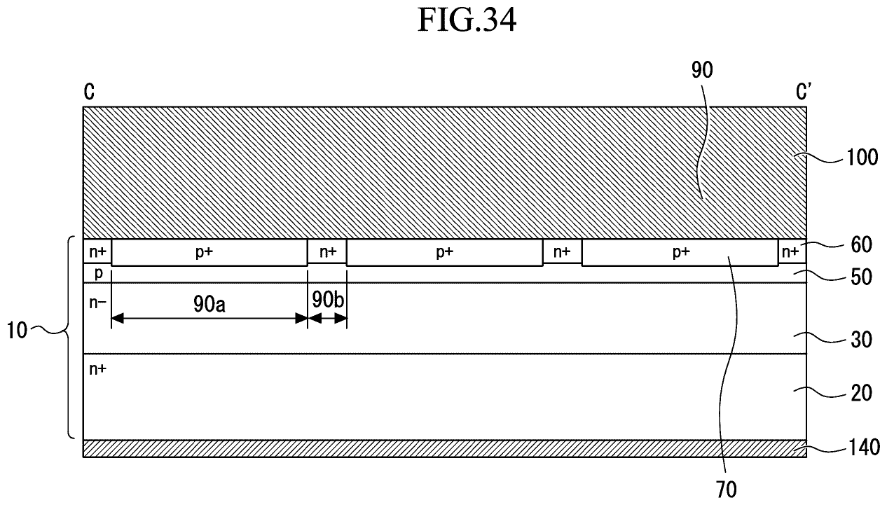

FIG. 34 is a sectional view taken along C-C′ in FIG. 31. Since FIG. 34 is the same figure as FIG. 30, description of FIG. 34 is omitted.

As described above, in the semiconductor apparatus 6000 according to the present embodiment, the width in the first direction 2 of the n+ type source layers 60 connected to the source electrode 100 by the contact holes 90 is set to be smaller than the width in the first direction 2 of the p+ type contact layers 70 connected to the source electrode 100 by the contact holes 90. As a result, it is possible to improve the short circuit tolerance.

The semiconductor apparatus 6000 according to the present embodiment does not include the n type base layer 40 in the region illustrated in FIG. 32. That is, the semiconductor apparatus 6000 includes a region where the p type base layers 50 and the n-type drift layer 30 are connected by only a path not via the n type base layer 40. In this region, a channel does not occur in a switching-on state. As a result, in the semiconductor apparatus 6000, since a channel region in the entire active region can be reduced, it is possible to reduce a saturation current and further improve the short circuit tolerance.

### Seventh Embodiment

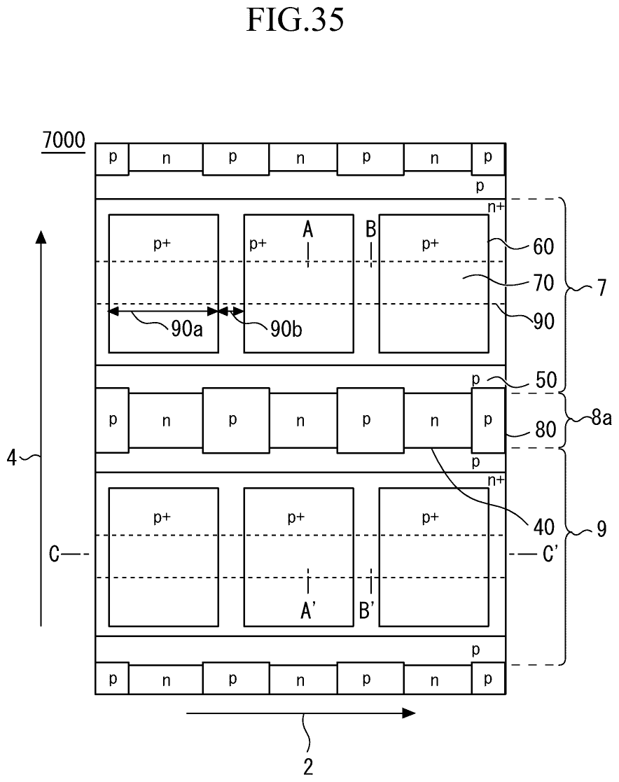

FIG. 35 is a plan view illustrating a configuration of a semiconductor apparatus according to a seventh embodiment of the present disclosure. FIG. 35 illustrates a plane layout of a cell region of a semiconductor apparatus 7000 that is a planar type MOSFET. The semiconductor apparatus 7000 is different from the semiconductor apparatus 5000 in that the semiconductor apparatus 7000 includes a JFET region 8a.

The JFET region 8a is positioned between the first region 7 and the second region 9. The JFET region 8a includes the n type base layer 40 extending in the first direction 2. Parts of the n type base layer 40 are covered with the p type diffusion layers 80. Specifically, the p type diffusion layers 80 and the n type base layers 40 are alternately positioned at fixed intervals in the first direction 2 in plan view. Regions sandwiched by the p type diffusion layers 80, the p+ type contact layer 70, and the other p+ type contact layer 70 are alternately positioned at fixed intervals in the second direction 4 in plan view.

The length in the first direction 2 of the p type diffusion layers 80 is larger than the length in the first direction 2 of the openings of the n contact holes 90b. That is, one ends in the first direction 2 of the p type diffusion layers 80 and one ends in the first direction 2 of the p+ type contact layers 70 are positioned side by side in the second direction 4. In a region where the one ends in the first direction 2 of the p type diffusion layers 80 and the one ends in the first direction 2 of the p+ type contact layers 70 are positioned side by side, a channel does not occur in a switching-on state. Note that this region is a region that is in contact with the n+ type source layers 60 connected to the source electrode 100 by the contact holes 90.

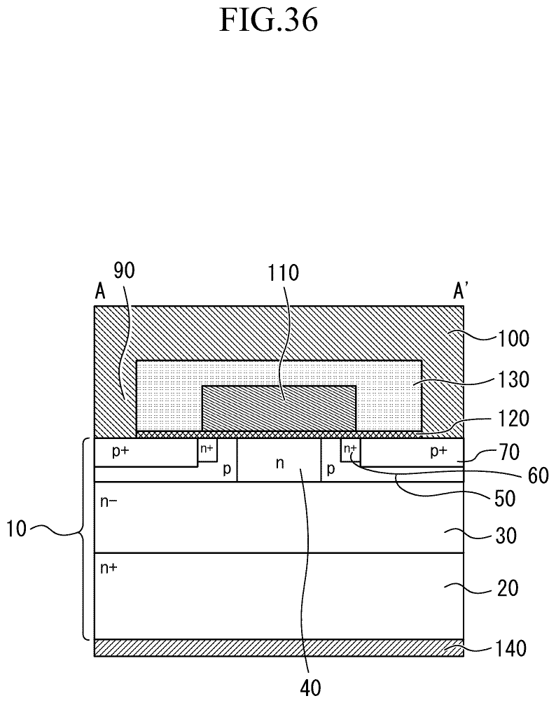

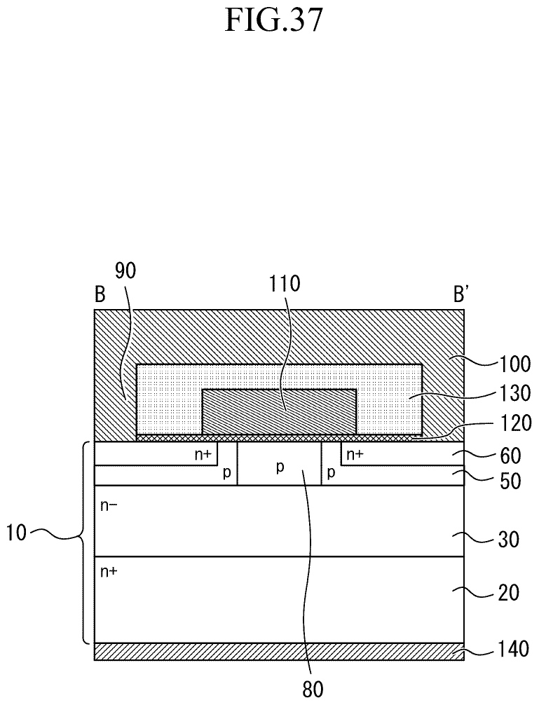

FIG. 36 is a sectional view taken along A-A′ in FIG. 35. Since FIG. 36 is the same figure as FIG. 28, description of FIG. 36 is omitted.

FIG. 37 is a sectional view taken along B-B′ in FIG. 35. FIG. 37 is different from FIG. 29 in that the semiconductor apparatus 7000 includes the p type diffusion layer 80 instead of the n type base layer 40.

The p type diffusion layer 80 is provided on the upper surface side of the n-type drift layer 30. The p type base layers 50 are provided on both sides of the p type diffusion layer 80. The gate oxide film 120 is provided on the p type diffusion layer 80, the p type base layers 50, and the n+ type source layers 60.

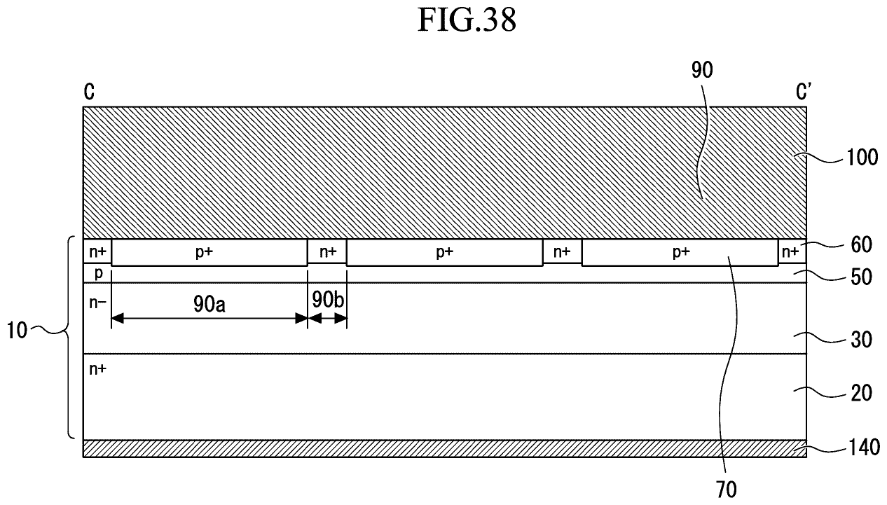

FIG. 38 is a sectional view taken along C-C′ in FIG. 35. Since FIG. 38 is the same figure as FIG. 30, description of FIG. 38 is omitted.

As described above, in the semiconductor apparatus 7000 according to the present embodiment, the width in the first direction 2 of the n+ type source layers 60 connected to the source electrode 100 by the contact holes 90 is set to be smaller than the width in the first direction 2 of the p+ type contact layers 70 connected to the source electrode 100 by the contact holes 90. As a result, it is possible to improve the short circuit tolerance.

The semiconductor apparatus 7000 according to the present embodiment does not include the n type base layer 40 in the region illustrated in FIG. 37. That is, the semiconductor apparatus 7000 includes a region where the p type base layers 50 and the n-type drift layer 30 are connected by only a path not via the n type base layer 40. In this region, a channel does not occur in a switching-on state. As a result, in the semiconductor apparatus 7000, since a channel region in the entire active region can be reduced, it is possible to reduce a saturation current and further improve the short circuit tolerance.

Further, in the semiconductor apparatus 7000 according to the present embodiment, in a region that is in contact with the n+ type source layers 60 connected to the source electrode 100 by the contact holes 90, a channel is not caused in the switching-on state. Regions of the n+ type source layers 60 connected to the source electrode 100 by the contact holes 90 are regions to which an electric current most easily flows in the switching-on state. For that reason, in the semiconductor apparatus 7000, since a channel is not caused in the regions to which an electric current most easily flows in the switching-on state, it is possible to prevent the electric current from concentrating on one place.

### Eighth Embodiment

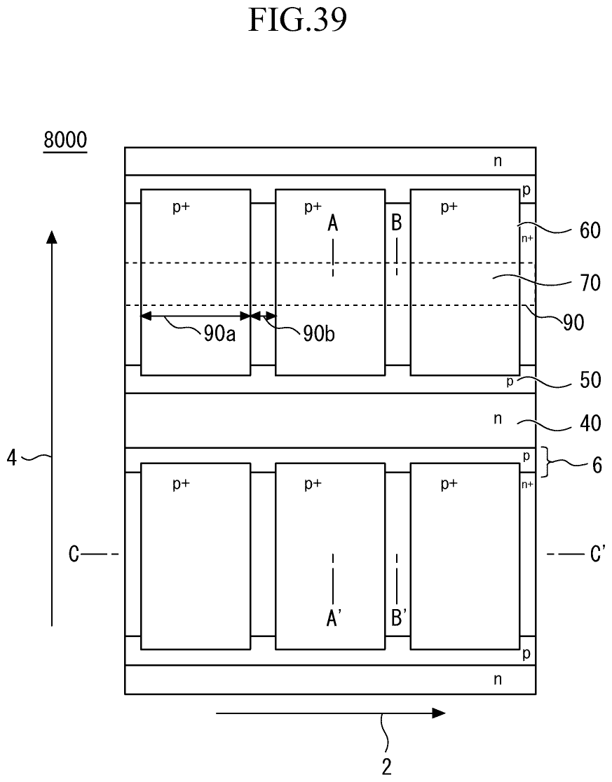

FIG. 39 is a plan view illustrating a configuration of a semiconductor apparatus according to an eighth embodiment of the present disclosure. FIG. 39 illustrates a plane layout of a cell region of a semiconductor apparatus 8000 that is a planar type MOSFET. The semiconductor apparatus 8000 is different from the semiconductor apparatus 5000 in that the p+ type contact layers 70 are longer in the second direction 4.

Parts of the n+ type source layers 60 and the p type base layers 50 are covered with the p+ type contact layers 70. The p+ type contact layers 70 are positioned in the first direction 2 to discretely cover the n+ type source layers 60 and the p type base layers 50. The length in the second direction 4 of the p+ type contact layers 70 is larger than the length in the second direction 4 of the n+ type source layers 60.

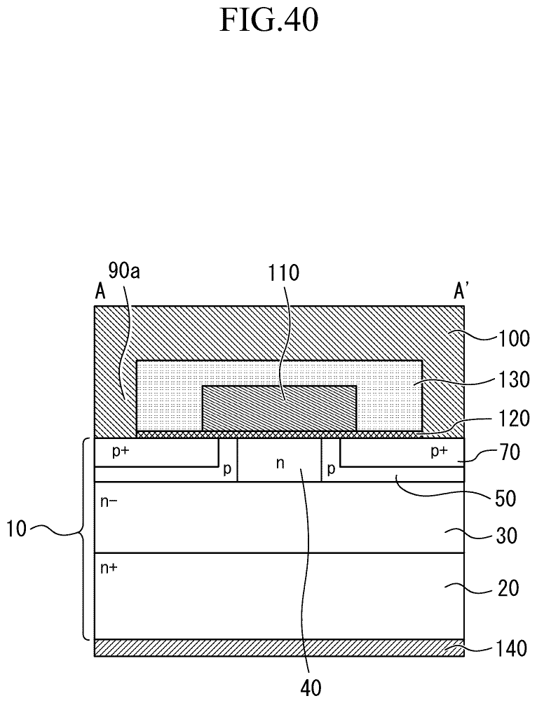

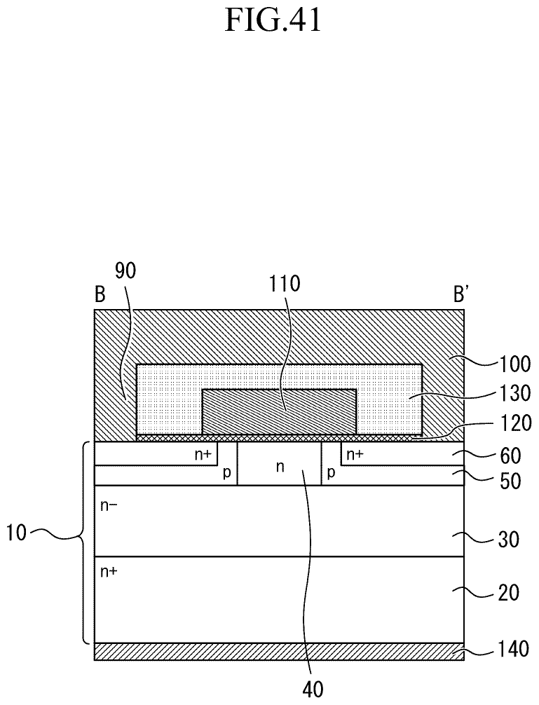

FIG. 40 is a sectional view taken along A-A′ in FIG. 39. Since FIG. 40 is the same figure as FIG. 20, description of FIG. 40 is omitted.

FIG. 41 is a sectional view taken along B-B′ in FIG. 39. Since FIG. 41 is the same figure as FIG. 29, description of FIG. 41 is omitted.

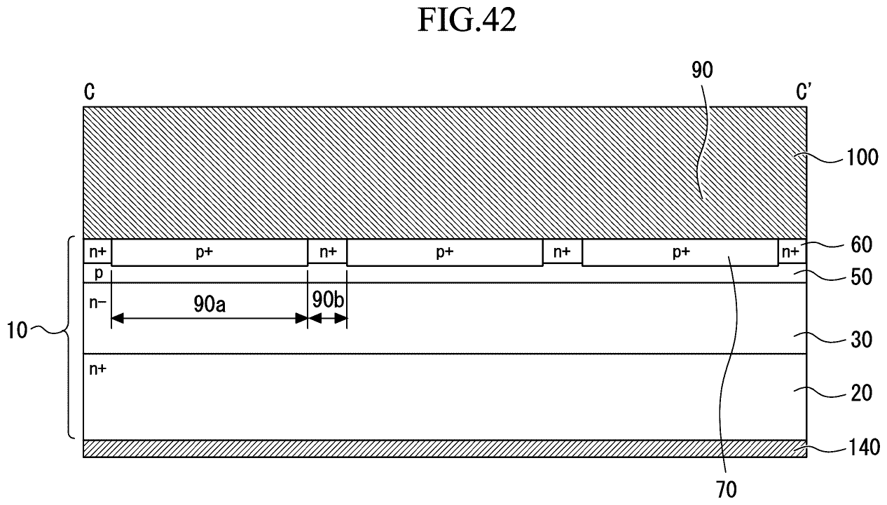

FIG. 42 is a sectional view taken along C-C′ in FIG. 39. Since FIG. 42 is the same figure as FIG. 30, description of FIG. 42 is omitted.

As described above, in the semiconductor apparatus 8000 according to the present embodiment, the width in the first direction 2 of the n+ type source layers 60 connected to the source electrode 100 by the contact holes 90 is set to be smaller than the width in the first direction 2 of the p+ type contact layers 70 connected to the source electrode 100 by the contact holes 90. As a result, it is possible to improve the short circuit tolerance.

The semiconductor apparatus 8000 according to the present embodiment does not include the N+ type source layers 60 in the region illustrated in FIG. 40. That is, the semiconductor apparatus 8000 includes a region where the p type base layers 50 and the p+ type contact layers 70 are connected by only a path not via the n+ type source layers 60. In this region, a channel does not occur in a switching-on state. As a result, in the semiconductor apparatus 8000, since a channel region in the entire active region can be reduced, it is possible to reduce a saturation current and further improve the short circuit tolerance.

Hereinafter, various aspects of the present disclosure will be collectively described as appendixes.

### (Appendix 1)

A semiconductor apparatus comprising:
a semiconductor substrate including a drift layer of a first conduction type, a first base layer of the first conduction type and a second base layer of a second conduction type provided side by side with each other on an upper surface side of the drift layer, a source layer of the first conduction type selectively provided on an upper surface side of the second base layer and having higher impurity concentration than the first base layer, and a contact layer of the second conduction type selectively provided on the upper surface side of the second base layer and having higher impurity concentration than the second base layer;
a gate oxide film provided on the first base layer, the second base layer, the source layer, and the contact layer;
a gate electrode provided on the gate oxide film;
an interlayer insulating film provided on the semiconductor substrate to cover the gate oxide film and the gate electrode and including a plurality of first contact holes that expose parts of the source layer and a plurality of second contact holes that expose parts of the contact layer;
a source electrode connected to the source layer via the first contact holes and connected to the contact layer via the second contact holes; and
a drain electrode connected to a lower surface side of the drift layer, wherein
the first contact holes and the second contact holes are separated by the interlayer insulating film.

### (Appendix 2)

The semiconductor apparatus according to appendix 1, wherein
openings of the first contact holes and openings of the second contact holes are alternately positioned in a first direction in plan view, and
a width in the first direction of the openings of the first contact holes is smaller than a width of the openings of the second contact holes.

### (Appendix 3)

The semiconductor apparatus according to appendix 1 or 2, wherein the openings of the first contact holes and the openings of the second contact holes have a same shape and a same size and are alternately positioned at fixed intervals in a first direction in plan view.

### (Appendix 4)

The semiconductor apparatus according to any one of appendixes 1 to 3, wherein
the openings of the first contact holes and the openings of the second contact holes have a same shape and a same size,
the first contact holes form a first contact hole group in which m pieces of the first contact holes are positioned at fixed intervals in a first direction,
the second contact holes form a second contact hole group in which n pieces of the second contact holes are positioned at fixed intervals in the first direction,
the first contact hole group and the second contact hole group are alternately positioned at fixed intervals in the first direction in plan view, and
m is a value of 1 or more and n or less.

### (Appendix 5)

A semiconductor apparatus comprising:
a semiconductor substrate including a drift layer of a first conduction type, a first base layer of the first conduction type and a second base layer of a second conduction type provided side by side with each other on an upper surface side of the drift layer, a source layer of the first conduction type selectively provided on an upper surface side of the second base layer and having higher impurity concentration than the first base layer, and a contact layer of the second conduction type selectively provided on the upper surface side of the second base layer and having higher impurity concentration than the second base layer;
a gate oxide film provided on the first base layer, the second base layer, the source layer, and the contact layer;
a gate electrode provided on the gate oxide film;
an interlayer insulating film provided on the semiconductor substrate to cover the gate oxide film and the gate electrode and including a plurality of first contact holes that expose parts of the source layer and a plurality of second contact holes that expose parts of the contact layer;
a source electrode connected to the source layer via the first contact holes and connected to the contact layer via the second contact holes; and
a drain electrode connected to a lower surface side of the drift layer, wherein
openings of the first contact holes and openings of the second contact holes are alternately positioned in a first direction in plan view, and
a width in the first direction of the openings of the first contact holes is smaller than a width in the first direction of the openings of the second contact holes.

### (Appendix 6)

The semiconductor apparatus according to any one of appendixes 1 to 5, wherein the semiconductor apparatus includes a region where the second base layer and the contact layer connected by only a path not via the source layer.

### (Appendix 7)

The semiconductor apparatus according to any one of appendixes 1 to 6, wherein
the semiconductor substrate further includes a diffusion layer of the second conduction type provided on the drift layer and under the gate oxide film,
a plurality of the contact layers are positioned at fixed intervals in a first direction in plan view,
the diffusion layer and the first base layer are alternately positioned at fixed intervals in the first direction in plan view,
the diffusion layer and the contact layer are alternately positioned at fixed intervals in a second direction that is a direction perpendicular to the first direction in plan view, and
the semiconductor apparatus includes a region where the second base layer and the drift layer are connected by only a path not via the first base layer.

### (Appendix 8)

The semiconductor apparatus according to any one of appendixes 1 to 7, wherein
the semiconductor substrate further includes a diffusion layer of the second conduction type provided on the drift layer and under the gate oxide film,
a plurality of the contact layers are positioned at fixed intervals in a first direction in plan view,
the diffusion layer and the first base layer are alternately positioned at fixed intervals in the first direction in plan view,
regions sandwiched by the diffusion layer, the contact layer, and another piece of the contact layer are alternately positioned at fixed intervals in a second direction that is a direction perpendicular to the first direction in plan view, and
the semiconductor apparatus includes a region where the second base layer and the drift layer are connected by only a path not via the first base layer.

### (Appendix 9)

The semiconductor apparatus according to any one of appendixes 1 to 8, wherein the semiconductor substrate is formed from a wide band gap semiconductor.

### (Appendix 10)

A method of manufacturing a semiconductor apparatus, comprising:
a step of forming a drift layer of a first conduction type on a semiconductor substrate;
a step of ion-implanting first impurities to an upper surface side of the drift layer to form a first base layer of the first conduction type;
a step of forming a first mask on an upper surface side of the first base layer and ion-implanting second impurities to form a second base layer of a second conduction type provided side by side with the first base layer on the upper surface side of the drift layer;
a step of forming a thin film on an upper surface and a sidewall of the first mask and an upper surface of the second base layer;
a step of etching the thin film to form a second mask including the first mask;
a step of ion-implanting the first impurities to upper surface sides of the second base layer and the second mask to form a source layer of the first conduction type selectively provided on the upper surface side of the second base layer;
a step of removing the second mask;
a step of selectively ion-implanting the second impurities to an upper surface side of the source layer to form a contact layer of the second conduction type selectively provided on the upper surface side of the second base layer;
a step of forming a gate oxide film on the first base layer, the second base layer, the source layer, and the contact layer;
a step of forming a gate electrode on the gate oxide film;
a step of forming an interlayer insulating film provided on the semiconductor substrate to cover the gate oxide film and the gate electrode and including a plurality of first contact holes that expose parts of the source layer and a plurality of second contact holes that expose parts of the contact layer;
a step of forming a source electrode connected to the source layer via the first contact holes and connected to the contact layer via the second contact holes; and
a step of forming a drain electrode on a lower surface side of the drift layer, wherein
the first contact holes and the second contact holes are separated by the interlayer insulating film.

### (Appendix 11)

A method of manufacturing a semiconductor apparatus, the method comprising:
a step of forming a drift layer of a first conduction type on a semiconductor substrate;
a step of ion-implanting first impurities to an upper surface side of the drift layer to form a first base layer of the first conduction type;
a step of forming a first mask on an upper surface side of the first base layer and ion-implanting second impurities to form a second base layer of a second conduction type provided side by side with the first base layer on the upper surface side of the drift layer;
a step of forming a thin film on an upper surface and a sidewall of the first mask and an upper surface of the second base layer;
a step of etching the thin film to form a second mask including the first mask;
a step of ion-implanting the first impurities to upper surface sides of the second base layer and the second mask to form a source layer of the first conduction type selectively provided on the upper surface side of the second base layer;
a step of removing the second mask;
a step of selectively ion-implanting the second impurities to an upper surface side of the source layer to form a contact layer of the second conduction type selectively provided on the upper surface side of the second base layer;
a step of forming a gate oxide film on the first base layer, the second base layer, the source layer, and the contact layer;
a step of forming a gate electrode on the gate oxide film;
a step of forming an interlayer insulating film provided on the semiconductor substrate to cover the gate oxide film and the gate electrode and including a plurality of first contact holes that expose parts of the source layer and a plurality of second contact holes that expose parts of the contact layer;
a step of forming a source electrode connected to the source layer via the first contact holes and connected to the contact layer via the second contact holes; and
a step of forming a drain electrode on a lower surface side of the drift layer, wherein
openings of the first contact holes and openings of the second contact holes are alternately positioned in a first direction in plan view, and
a width in the first direction of the openings of the first contact holes is smaller than a width in the first direction of the openings of the second contact holes.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-093876, filed on Jun. 10, 2024 including specification, claims, drawings and summary, on which the Convention priority of the present application is based, are incorporated herein by reference in its entirety.

1. A semiconductor apparatus comprising:
a semiconductor substrate including a drift layer of a first conduction type, a first base layer of the first conduction type and a second base layer of a second conduction type provided side by side with each other on an upper surface side of the drift layer, a source layer of the first conduction type selectively provided on an upper surface side of the second base layer and having higher impurity concentration than the first base layer, and a contact layer of the second conduction type selectively provided on the upper surface side of the second base layer and having higher impurity concentration than the second base layer;
a gate oxide film provided on the first base layer, the second base layer, the source layer, and the contact layer;
a gate electrode provided on the gate oxide film;
an interlayer insulating film provided on the semiconductor substrate to cover the gate oxide film and the gate electrode and including a plurality of first contact holes that expose parts of the source layer and a plurality of second contact holes that expose parts of the contact layer;
a source electrode connected to the source layer via the first contact holes and connected to the contact layer via the second contact holes; and
a drain electrode connected to a lower surface side of the drift layer, wherein
the first contact holes and the second contact holes are separated by the interlayer insulating film.

2. The semiconductor apparatus according to claim 1, wherein
openings of the first contact holes and openings of the second contact holes are alternately positioned in a first direction in plan view, and
a width in the first direction of the openings of the first contact holes is smaller than a width of the openings of the second contact holes.

3. The semiconductor apparatus according to claim 1, wherein the openings of the first contact holes and the openings of the second contact holes have a same shape and a same size and are alternately positioned at fixed intervals in a first direction in plan view.

4. The semiconductor apparatus according to claim 1, wherein
the openings of the first contact holes and the openings of the second contact holes have a same shape and a same size,
the first contact holes form a first contact hole group in which m pieces of the first contact holes are positioned at fixed intervals in a first direction,
the second contact holes form a second contact hole group in which n pieces of the second contact holes are positioned at fixed intervals in the first direction,
the first contact hole group and the second contact hole group are alternately positioned at fixed intervals in the first direction in plan view, and
m is a value of 1 or more and n or less.

5. A semiconductor apparatus comprising:
a semiconductor substrate including a drift layer of a first conduction type, a first base layer of the first conduction type and a second base layer of a second conduction type provided side by side with each other on an upper surface side of the drift layer, a source layer of the first conduction type selectively provided on an upper surface side of the second base layer and having higher impurity concentration than the first base layer, and a contact layer of the second conduction type selectively provided on the upper surface side of the second base layer and having higher impurity concentration than the second base layer;
a gate oxide film provided on the first base layer, the second base layer, the source layer, and the contact layer;
a gate electrode provided on the gate oxide film;
an interlayer insulating film provided on the semiconductor substrate to cover the gate oxide film and the gate electrode and including a plurality of first contact holes that expose parts of the source layer and a plurality of second contact holes that expose parts of the contact layer;
a source electrode connected to the source layer via the first contact holes and connected to the contact layer via the second contact holes; and
a drain electrode connected to a lower surface side of the drift layer, wherein
openings of the first contact holes and openings of the second contact holes are alternately positioned in a first direction in plan view, and
a width in the first direction of the openings of the first contact holes is smaller than a width in the first direction of the openings of the second contact holes.

6. The semiconductor apparatus according to claim 1, wherein the semiconductor apparatus includes a region where the second base layer and the contact layer connected by only a path not via the source layer.

7. The semiconductor apparatus according to claim 1, wherein
the semiconductor substrate further includes a diffusion layer of the second conduction type provided on the drift layer and under the gate oxide film,
a plurality of the contact layers are positioned at fixed intervals in a first direction in plan view,
the diffusion layer and the first base layer are alternately positioned at fixed intervals in the first direction in plan view,
the diffusion layer and the contact layer are alternately positioned at fixed intervals in a second direction that is a direction perpendicular to the first direction in plan view, and
the semiconductor apparatus includes a region where the second base layer and the drift layer are connected by only a path not via the first base layer.

8. The semiconductor apparatus according to claim 1, wherein
the semiconductor substrate further includes a diffusion layer of the second conduction type provided on the drift layer and under the gate oxide film,
a plurality of the contact layers are positioned at fixed intervals in a first direction in plan view,
the diffusion layer and the first base layer are alternately positioned at fixed intervals in the first direction in plan view,
regions sandwiched by the diffusion layer, the contact layer, and another piece of the contact layer are alternately positioned at fixed intervals in a second direction that is a direction perpendicular to the first direction in plan view, and
the semiconductor apparatus includes a region where the second base layer and the drift layer are connected by only a path not via the first base layer.

9. The semiconductor apparatus according to claim 1, wherein the semiconductor substrate is formed from a wide band gap semiconductor.

10. A method of manufacturing a semiconductor apparatus, comprising:
a step of forming a drift layer of a first conduction type on a semiconductor substrate;
a step of ion-implanting first impurities to an upper surface side of the drift layer to form a first base layer of the first conduction type;
a step of forming a first mask on an upper surface side of the first base layer and ion-implanting second impurities to form a second base layer of a second conduction type provided side by side with the first base layer on the upper surface side of the drift layer;
a step of forming a thin film on an upper surface and a sidewall of the first mask and an upper surface of the second base layer;
a step of etching the thin film to form a second mask including the first mask;
a step of ion-implanting the first impurities to upper surface sides of the second base layer and the second mask to form a source layer of the first conduction type selectively provided on the upper surface side of the second base layer;
a step of removing the second mask;
a step of selectively ion-implanting the second impurities to an upper surface side of the source layer to form a contact layer of the second conduction type selectively provided on the upper surface side of the second base layer;
a step of forming a gate oxide film on the first base layer, the second base layer, the source layer, and the contact layer;
a step of forming a gate electrode on the gate oxide film;
a step of forming an interlayer insulating film provided on the semiconductor substrate to cover the gate oxide film and the gate electrode and including a plurality of first contact holes that expose parts of the source layer and a plurality of second contact holes that expose parts of the contact layer;
a step of forming a source electrode connected to the source layer via the first contact holes and connected to the contact layer via the second contact holes; and
a step of forming a drain electrode on a lower surface side of the drift layer, wherein
the first contact holes and the second contact holes are separated by the interlayer insulating film.

11. A method of manufacturing a semiconductor apparatus, the method comprising:
a step of forming a drift layer of a first conduction type on a semiconductor substrate;
a step of ion-implanting first impurities to an upper surface side of the drift layer to form a first base layer of the first conduction type;
a step of forming a first mask on an upper surface side of the first base layer and ion-implanting second impurities to form a second base layer of a second conduction type provided side by side with the first base layer on the upper surface side of the drift layer;
a step of forming a thin film on an upper surface and a sidewall of the first mask and an upper surface of the second base layer;
a step of etching the thin film to form a second mask including the first mask;
a step of ion-implanting the first impurities to upper surface sides of the second base layer and the second mask to form a source layer of the first conduction type selectively provided on the upper surface side of the second base layer;
a step of removing the second mask;
a step of selectively ion-implanting the second impurities to an upper surface side of the source layer to form a contact layer of the second conduction type selectively provided on the upper surface side of the second base layer;
a step of forming a gate oxide film on the first base layer, the second base layer, the source layer, and the contact layer;
a step of forming a gate electrode on the gate oxide film;
a step of forming an interlayer insulating film provided on the semiconductor substrate to cover the gate oxide film and the gate electrode and including a plurality of first contact holes that expose parts of the source layer and a plurality of second contact holes that expose parts of the contact layer;
a step of forming a source electrode connected to the source layer via the first contact holes and connected to the contact layer via the second contact holes; and
a step of forming a drain electrode on a lower surface side of the drift layer, wherein
openings of the first contact holes and openings of the second contact holes are alternately positioned in a first direction in plan view, and
a width in the first direction of the openings of the first contact holes is smaller than a width in the first direction of the openings of the second contact holes.

12. The semiconductor apparatus according to claim 5, wherein the semiconductor apparatus includes a region where the second base layer and the contact layer connected by only a path not via the source layer.

13. The semiconductor apparatus according to claim 5, wherein
the semiconductor substrate further includes a diffusion layer of the second conduction type provided on the drift layer and under the gate oxide film,
a plurality of the contact layers are positioned at fixed intervals in a first direction in plan view,
the diffusion layer and the first base layer are alternately positioned at fixed intervals in the first direction in plan view,
the diffusion layer and the contact layer are alternately positioned at fixed intervals in a second direction that is a direction perpendicular to the first direction in plan view, and
the semiconductor apparatus includes a region where the second base layer and the drift layer are connected by only a path not via the first base layer.

14. The semiconductor apparatus according to claim 5, wherein
the semiconductor substrate further includes a diffusion layer of the second conduction type provided on the drift layer and under the gate oxide film,
a plurality of the contact layers are positioned at fixed intervals in a first direction in plan view,
the diffusion layer and the first base layer are alternately positioned at fixed intervals in the first direction in plan view,
regions sandwiched by the diffusion layer, the contact layer, and another piece of the contact layer are alternately positioned at fixed intervals in a second direction that is a direction perpendicular to the first direction in plan view, and
the semiconductor apparatus includes a region where the second base layer and the drift layer are connected by only a path not via the first base layer.

15. The semiconductor apparatus according to claim 5, wherein the semiconductor substrate is formed from a wide band gap semiconductor.
